(19) United States
(12) Patent Application Publication
(10) Pub. No.: US 2026/0247699 A1
(43) Pub. Date: Aug. 20, 2026

(54) SEMICONDUCTOR DEVICES AND METHODS OF FORMING

(71) Applicant: Taiwan Semiconductor Manufacturing Co., Ltd., Hsinchu (TW)

(72) Inventor: Han Yeh, Hsinchu (TW)

(21) Appl. No.: 19/402,656

(22) Filed: Nov. 26, 2025

Related U.S. Application Data
(63) Continuation-in-part of application No. 19/259,949, filed on Jul. 3, 2025.
(60) Provisional application No. 63/760,484, filed on Feb. 19, 2025.

(51) Int. Cl. H10D 84/83; H01L 23/522; H01L 23/528; H10D 30/00; H10D 30/01; H10D 30/43; H10D 62/10; H10D 62/13; H10D 84/01

(52) U.S. Cl. CPC H10D 84/832; H10D 30/014; H10D 30/0191; H10D 30/43; H10D 30/503; H10D 62/102; H10D 62/121; H10D 62/151; H10D 84/0149; H10W 20/42; H10W 20/435

(57) ABSTRACT

A middle contact etch stop layer (MCESL) with a multi-layered structure is formed over the interlayer-dielectric layer (ILD) and the gate structure of a semiconductor device, and an interconnect structure is then formed on the MCESL. The MCESL includes a first dielectric layer (e.g., SiOCN), a second dielectric layer (e.g., SiOC), and a third dielectric layer (e.g., SiO) formed successively over the ILD and the gate structure. A dielectric constant of the first dielectric layer is higher than that of the second dielectric layer and that of the third dielectric layer. The first dielectric layer performs most of etch stopping function of the MCESL. The second dielectric layer helps to reduce the overall dielectric constant of the MCESL, and also functions as a buffer layer to reduce downward oxygen diffusion from the third dielectric layer into the gate structure. The third dielectric layer helps to achieve improved photolithography quality.

### PRIORITY CLAIM AND CROSS-REFERENCE

This application is a continuation-in-part of U.S. patent application Ser. No. 19/259,949, filed on Jul. 3, 2025 and entitled “Semiconductor Devices and Methods of Forming,” which claims priority to U.S. Provisional Patent Application No. 63/760,484, filed on Feb. 19, 2025 and entitled “Bilayer MCESL,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 14A, 14B, 14C, 15A, 15B, 16A and 16B illustrate various views of a nanostructure field-effect transistor (NSFET) device at various stages of manufacturing, in accordance with an embodiment.

FIGS. 17A and 17B illustrate cross-sectional views of an NSFET device, in accordance with another embodiment.

FIGS. 18A, 18B, 19A, and 19B illustrate cross-sectional views of an NSFET device at various stages of manufacturing, in accordance with another embodiment.

FIGS. 20A, 20B, and 20C illustrate cross-sectional views of an NSFET device, in accordance with another embodiment.

FIG. 21 illustrates a flow chart of a method of forming a semiconductor device, in accordance with some embodiments.

FIGS. 22A, 22B, 23A, 23B, 24, 25, 26A, and 26B illustrate cross-sectional views of an NSFET device at various stages of manufacturing, in accordance with another embodiment.

FIGS. 27A and 27B illustrate cross-sectional views of an NSFET device, in accordance with yet another embodiment.

FIGS. 28A and 28B together illustrate a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

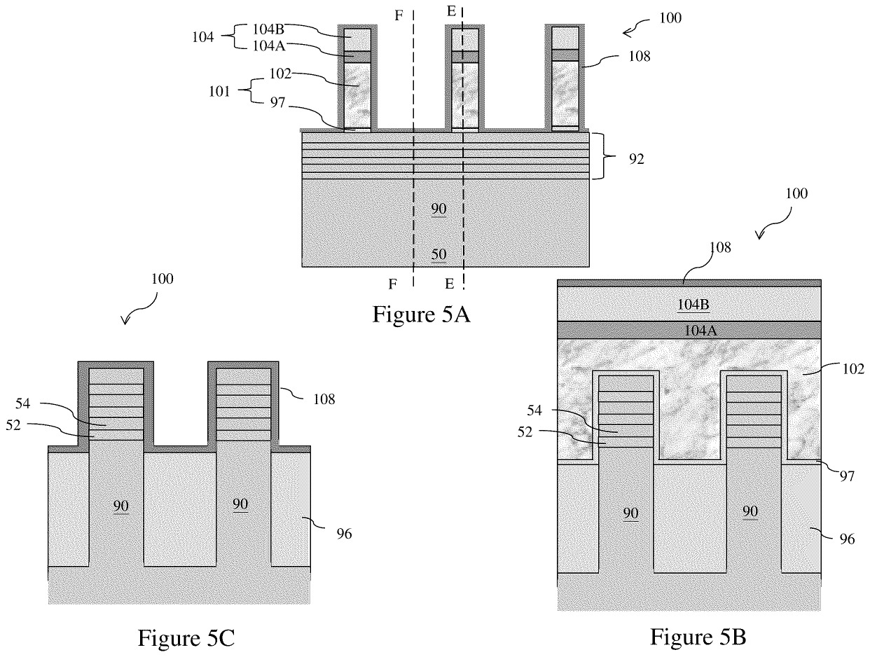

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIG. 5A-5C) illustrate different views of the same device at the same stage of processing.

Various embodiments of the present disclosure are discussed in the context of forming a nanostructure field-effect transistor (NSFET) device, with the understanding that the disclosed features, such as the middle contact etch stop layer (MCESL) with a multi-layered structure may also be applied to other types of semiconductor devices, such as fin field-effect transistor (FinFET) devices, planar devices, or the like.

In some embodiments, an MCESL with a multi-layered structure is formed over the interlayer-dielectric layer (ILD) and the gate structure of a semiconductor device, and an interconnect structure is then formed on the MCESL. The MCESL includes a first dielectric layer (e.g., SiOCN), a second dielectric layer (e.g., SiOC), and a third dielectric layer (e.g., SiO) formed successively over the ILD and the gate structure. In some embodiments, the first dielectric layer is a nitride material that has a high density/dielectric constant, but low etch rate. The second dielectric layer has a low density/dielectric constant and a lower atomic percentage of oxygen than the third dielectric layer. The third dielectric layer has a higher density/hardness than the second dielectric layer. The first dielectric layer performs most of etch stopping function of the MCESL. The second dielectric layer helps to reduce the overall dielectric constant of the MCESL, and also functions as a buffer layer to reduce downward oxygen diffusion from the third dielectric layer into the gate structure. The third dielectric layer helps to achieve improved photolithography quality. The multi-layered MCESL offers many parameters to tune the MCESL to achieve a balance between different performance criteria, such as low parasitic capacitance, low oxygen penetration, high photolithography quality, and high device performance (e.g., faster switching speed and/or lower power consumption).

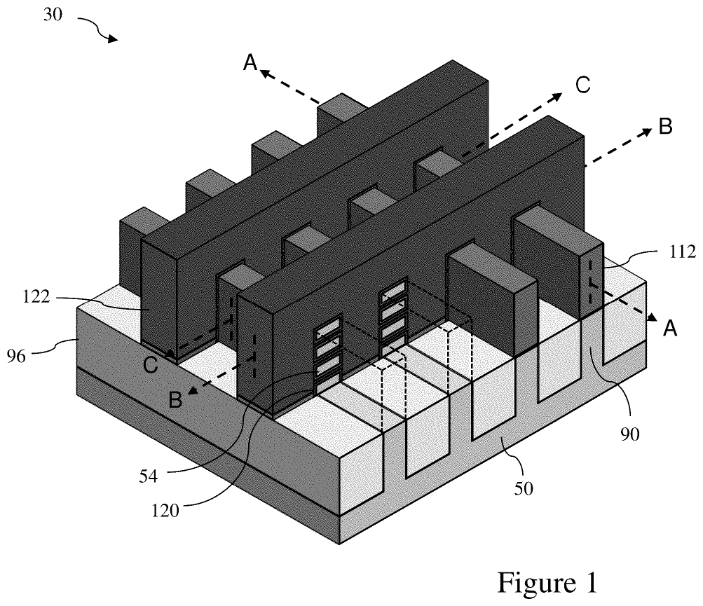

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Subsequent figures may refer to these reference cross-sections for clarity.

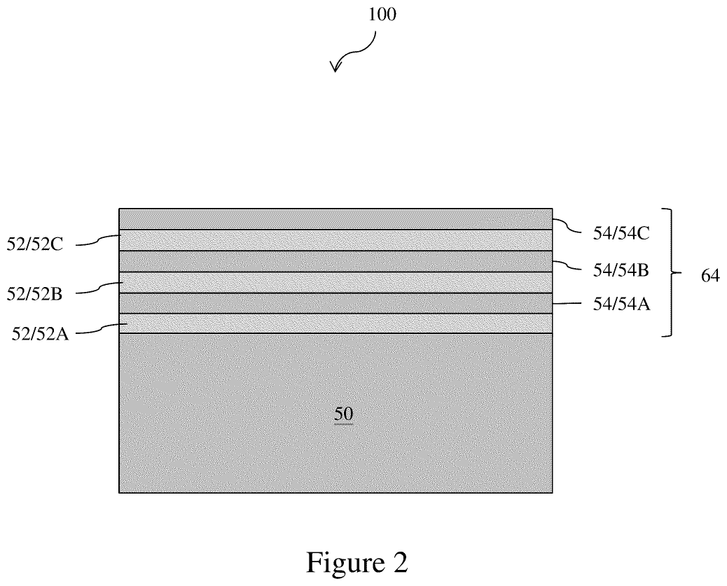

FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 14A, 14B, 14C, 15A, 15B, 16A and 16B illustrate various views (e.g., cross-sectional view, top view) of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type and p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. For example, the multi-layer stack 64 may be patterned and etched to form nanostructures (e.g., nanosheets or nanowires), with the channel regions of the resulting NSFET including nanostructures that are vertically stacked over a fin, and with each nanostructure extending parallel to a major upper surface of the substrate.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

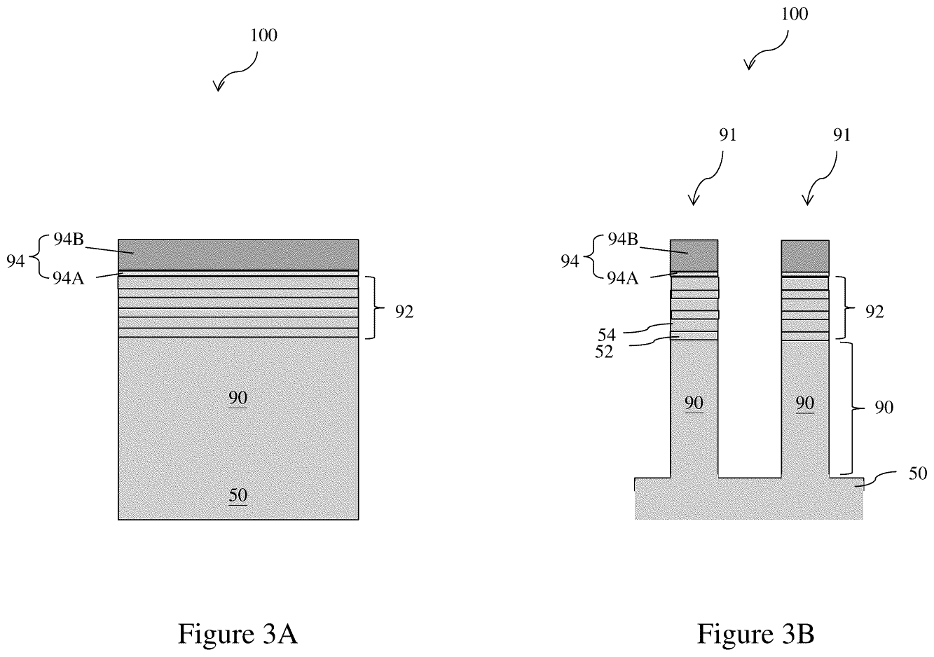

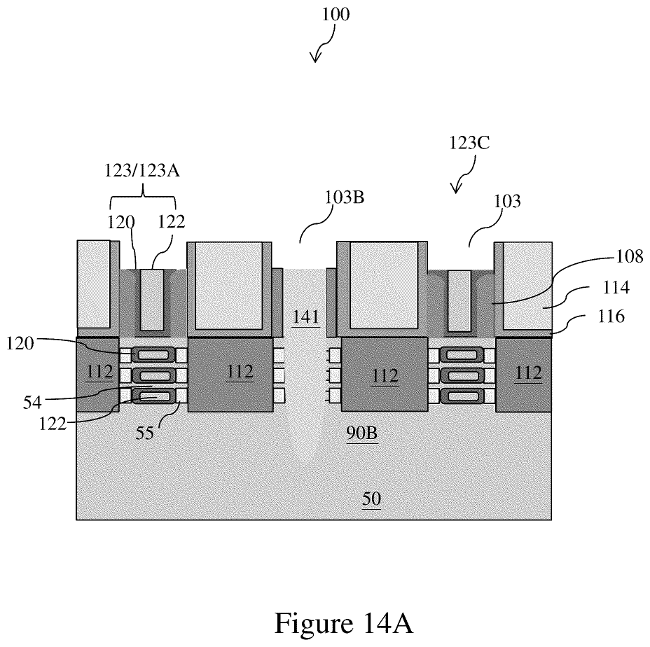

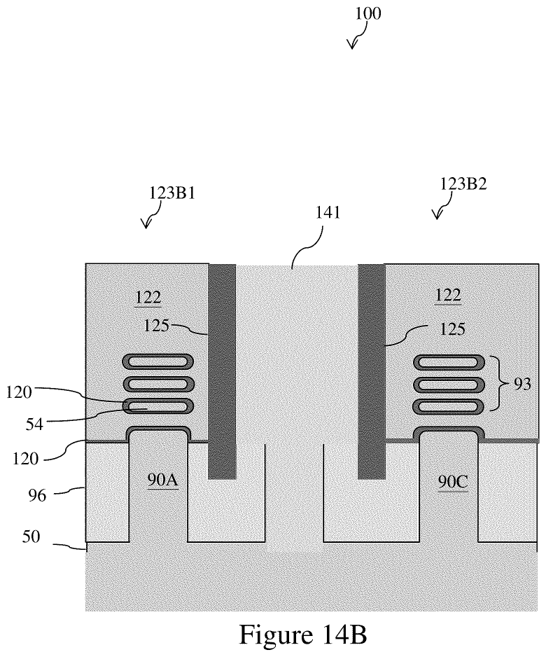

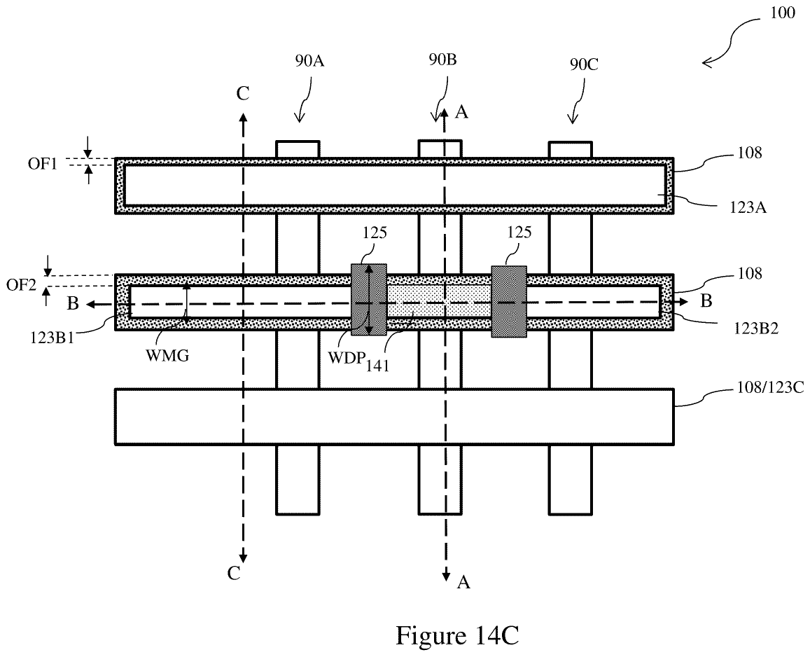

FIGS. 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 14A, 14B, 14C, 15A, 15B, 16A and 16B illustrate various views (e.g., cross-sectional view, top view) of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, and 16A are cross-sectional views along cross-section A-A in FIG. 1. FIGS. 3B, 4B, 5B, 6B, 7B, 8B, 9B, 10B, 11B, 12B, 13B, 14B, 15B, and 16B are cross-sectional views along cross-section B-B in FIG. 1. FIGS. 5C, 6C, and 7C are cross-sectional views along cross-section C-C in FIG. 1. FIG. 14C is a top view of the NSFET device 100. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIGS. 3A and 3B. The unetched lower portion of the substrate 50 is referred to as substrate 50 in FIGS. 3A and 3B (and subsequent figures). Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have substantially perpendicular sidewalls (e.g. perpendicular to the major upper surface of the substrate 50). The shapes of the fins 90 and the layer stacks 92 illustrated in FIG. 3B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls for the fins 90 and the layer stacks 92.

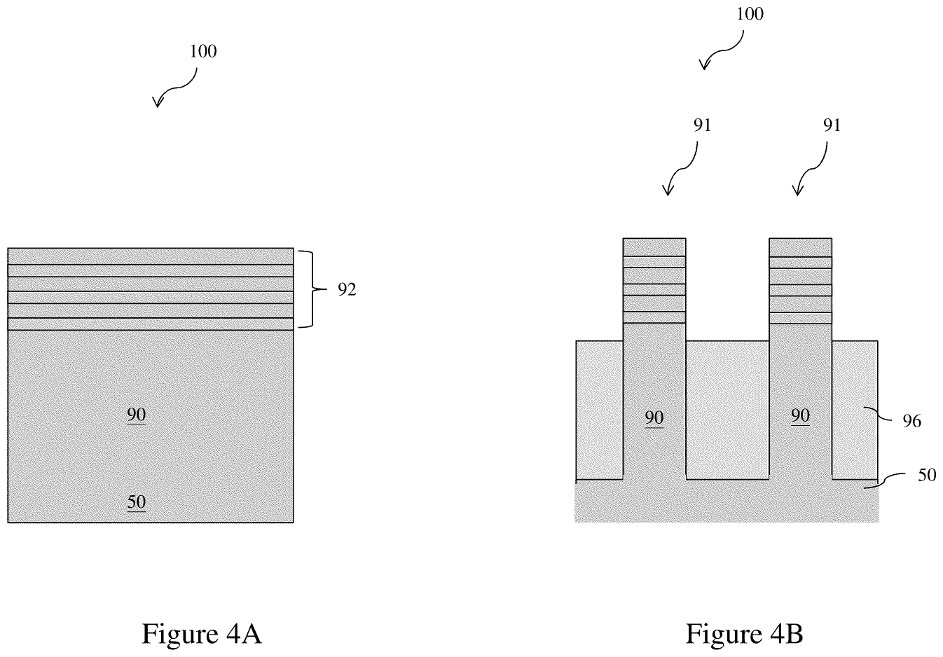

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a chemical mechanical planarization (CMP) process, an etch back process, a combination thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 5A-5C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by CMP. The dummy gate layer may be a suitable material selected from a group including amorphous silicon, polycrystalline-silicon (polysilicon), poly-crystalline silicon-germanium (poly-SiGe), and the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, a combination thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. The dielectric constant (also referred to as K value) of the gate spacer 108 may be between about 5.0 and about 7.0, as an example. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

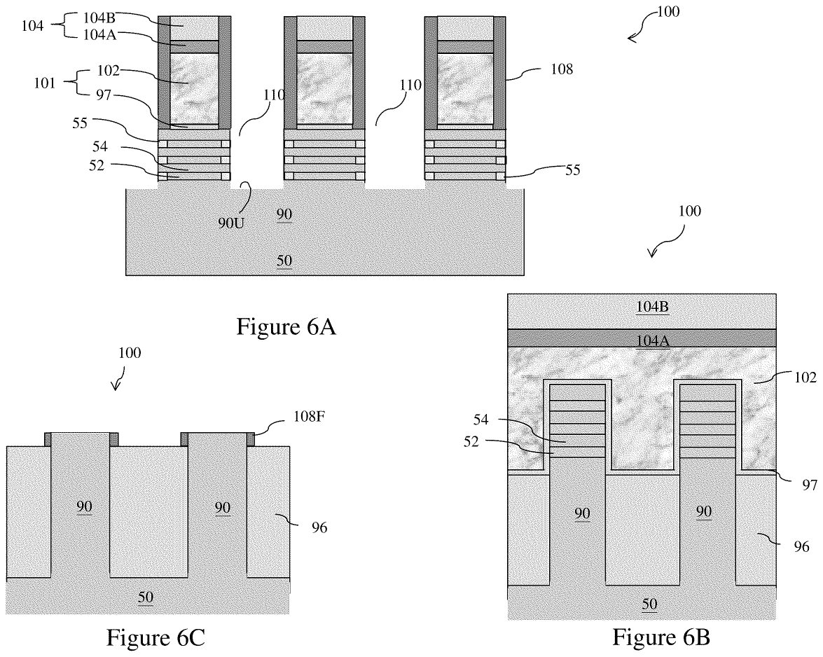

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections B-B and C-C in FIG. 1, respectively. Unless otherwise specified, subsequent figures with alphabets A, B and C (e.g., FIGS. 6A, 6B, and 6C) illustrate cross-sectional views along the same cross-sections as FIGS. 5A, 5B, and 5C, respectively.

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates structures 101), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110 to line sidewalls and bottoms of the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. The dielectric constant of the inner spacer layer may be between about 3.0 and about 4.0, as an example. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

In the example of FIG. 6C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F. In FIG. 6C, the upper surface of the STI regions 96 between neighboring fins 90 is illustrated as a flat surface as a non-limiting example. The upper surface of the STI regions 96 between neighboring fins 90 may be curved (e.g., concave), e.g., due to the anisotropic etching process removing upper portions of the STI regions 96.

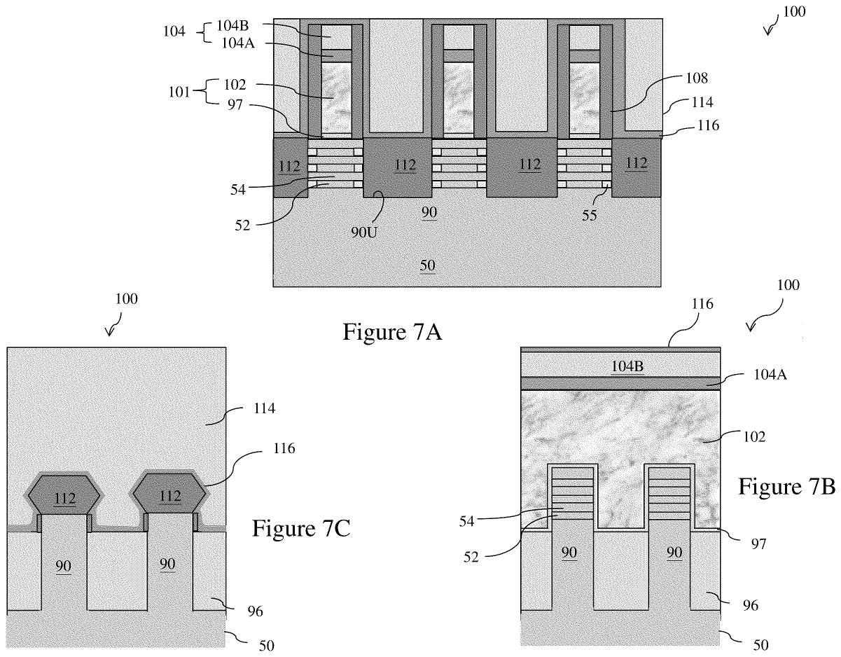

Next, in FIG. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

In some embodiments, the epitaxial source/drain regions 112 are formed by epitaxially growing a material in the openings 110, using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7C) after the epitaxy process is completed. In other embodiments, these facets cause adjacent epitaxial source/drain regions 112 to merge together.

Next, a contact etch stop layer (CESL) 116 is formed (e.g., conformally) over the source/drain regions 112, along sidewalls of the gate spacers 108, and over the dummy gate structures 101. Next, an inter-layer dielectric (ILD) 114 is then deposited over the CESL 116. The CESL 116 is formed of a material having a different etch rate than the ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used. The dielectric constant of the CESL 116 may be between about 6.5 and about 7.0, as an example.

The ILD 114 may be formed of a dielectric material, and may be deposited by any suitable method, such as CVD, PECVD, or FCVD. Dielectric materials for the ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. The dielectric constant of the ILD 114 may be between about 3.9 and about 4.1, as an example.

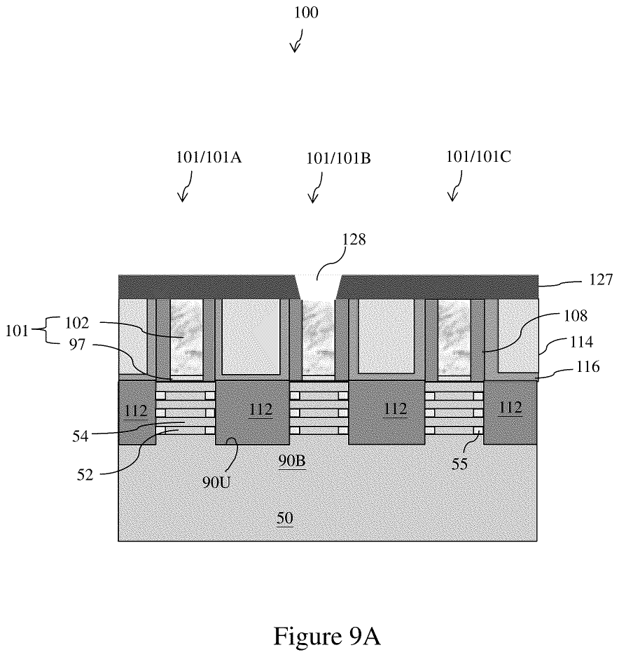

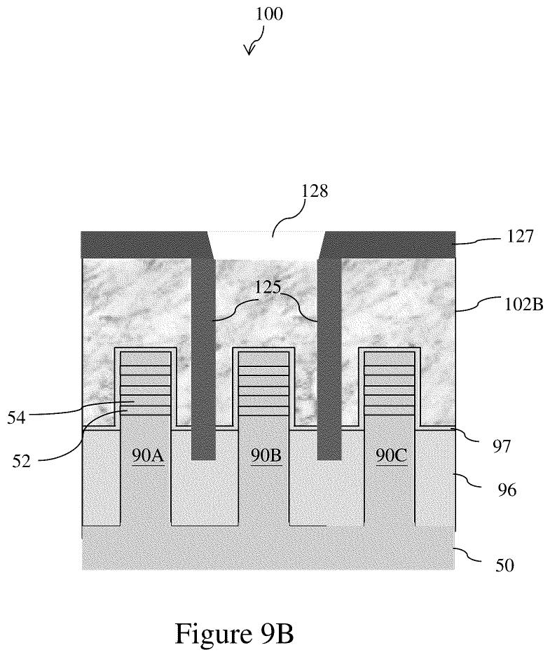

In FIGS. 7A and 7B, two fins 90 and three dummy gate structures 101 are illustrated. This is, of course, a non-limiting example. The number of fins 90 and the number of gate structures in the NSFET device 100 may be any suitable number. In subsequent figures (e.g., FIG. 9A-16B), to facilitate discussion of a Cut Poly On Diffusion Edge (CPODE) process (where the cutting of the gate structures and the cutting of the nanostructures are performed on the dummy gate structures before the replacement gate structures are formed), three fins 90 (which are labeled as 90A, 90B, and 90C) and three dummy gate structures 101 (which are labeled as 101A, 101B, and 101C) are illustrated. Note that for simplicity, the cross-sectional views along cross-section F-F illustrated in FIG. 5A are not illustrated for processing steps hereinafter, because such cross-sectional views are the same as or similar to FIG. 7C, or may be easily modified from FIG. 7C (e.g., by adding additional layers formed over the ILD 114).

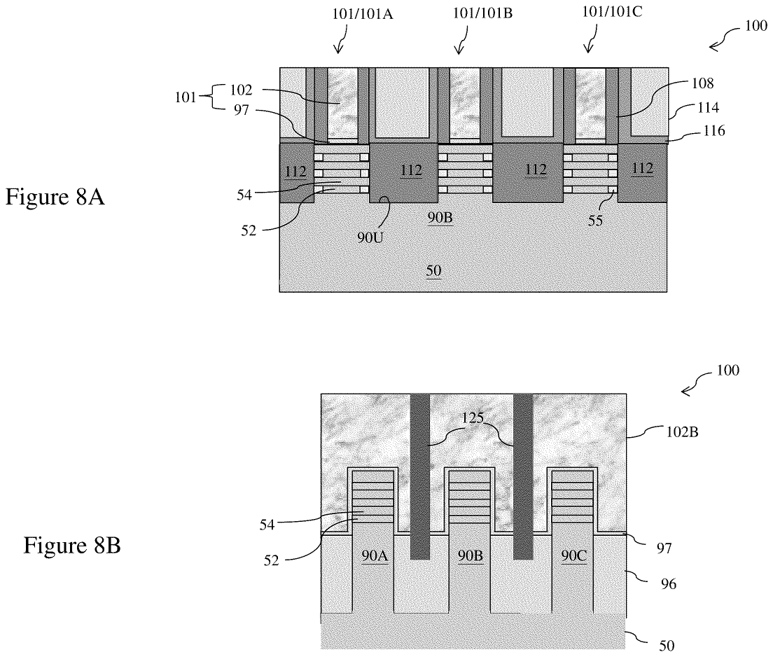

Next, in FIGS. 8A and 8B, a planarization process, such as CMP, is performed to level the top surfaces of the ILD 114 and CESL 116 with the top surfaces of the dummy gate structures 101 and gate spacers 108. The planarization process may also remove the masks 104 (see FIG. 7A) on the dummy gate structures 101, and portions of the gate spacers 108 along sidewalls of the masks 104. After the planarization process, top surfaces of the dummy gate structures 101, gate spacers 108, CESL 116, and ILD 114 are level. Accordingly, the top surfaces of the dummy gate structures 101A, 101B, and 101C (collectively referred to as dummy gate structures 101) are exposed at the top surface of the ILD 114.

Next, dielectric plugs 125 are formed to cut the dummy gate structure 101B into a plurality of separate segments. In FIG. 8B, reference numeral 102B is used to refer to the dummy gate of the dummy gate structure 101B. The top view in FIG. 14C illustrates the locations of the dielectric plugs 125 relative to the fins 90 and the subsequently formed replacement gate structures 123. Details are discussed hereinafter.

In some embodiments, the dielectric plugs 125 are formed by forming openings in the dummy gate structure 101B and the ILD 114 (e.g., using photolithography and etching techniques), and filling the openings with a dielectric material, such as silicon nitride, silicon oxide, combinations thereof, or the like. Next, a planarization process, such as CMP, may be performed to remove excess portions of the dielectric material from the upper surface of the ILD 114, and the remaining portions of the dielectric material in the openings form the dielectric plugs 125.

In the illustrated example of FIG. 8B, the dielectric plugs 125 are formed on opposing sides of the fin 90B. For example, one of the dielectric plugs 125 is formed between the fins 90A and 90B, and another one of the dielectric plugs 125 is formed between the fins 90B and 90C. A dimension WDP (see FIG. 14C) of the dielectric plug 125, measured along the direction of cross-section A-A in FIG. 14C, is larger than a dimension WMG (see FIG. 14C) of the dummy gate structure 101B (or the replacement gate structure 123B1 or 123B2) to ensure that the dielectric plugs 125 cut the dummy gate structure 101B into separate segments that are electrically isolated from each other, in the illustrated embodiment. As shown in FIG. 8B, the dielectric plugs 125 extend through the dummy gate structure 101B and into the STI regions 96 to ensure separation of the different segments of the dummy gate structure 101B. Note that the dielectric plugs 125 are not in the cross-section A-A (see FIG. 14C), thus are not visible in FIG. 8A.

Next, in FIGS. 9A and 9B, a hard mask layer 127 (may also be referred to as a mask layer 127) is formed over the ILD 114 and the dummy gate structures 101. The hard mask layer 127 may be a single-layer hard mask formed of, e.g., silicon nitride, silicon oxynitride, or the like, using a suitable formation method such as CVD. In some embodiments, the hard mask layer 127 has a multi-layered structure. For example, the hard mask layers 127 may include a silicon layer sandwiched between two silicon nitride layers. Next, an opening 128 is formed in the hard mask layer 127, e.g., using photolithography and etching techniques. The opening 128 is formed to expose a portion of the dummy gate structure 101B disposed between the dielectric plugs 125.

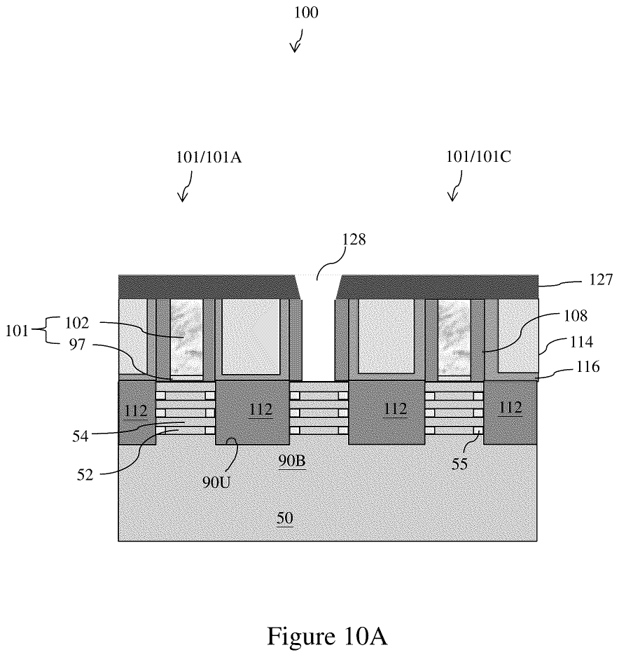

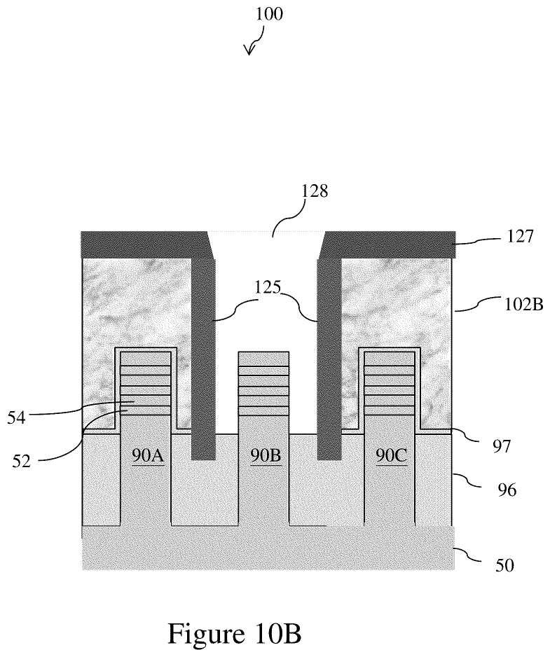

Next, in FIGS. 10A and 10B, a portion of the dummy gate structure 101B exposed by (e.g., underlying) the opening 128 is removed (e.g., completely removed) by, e.g., an isotropic etching process. The opening 128 is therefore extended downward through the dummy gate structure 101B. In some embodiments, the isotropic etching process is a wet etching process performed using an etching chemical (e.g., an etching fluid). The etching fluid may comprise potassium hydroxide (KOH), sodium hydroxide (NaOH), tetramethylammonium hydroxide (TMAH), combinations thereof, or the like, as an example. The etching fluid may comprise hydrogen fluoride acid (HF), nitric acid (HNO₃), combinations thereof, or the like, as another example. In some embodiments, the isotropic etching process is a dry etching process (e.g., a plasma etching process) performed using an etching gas comprising H₂, NF₃, combinations thereof, or the like. The hard mask layer 127, the gate spacers 108, and the dielectric plugs 125 may help to protect (e.g., shield) other areas of the NSFET device 100 from the isotropic etching process, and limit the effect of the isotropic etching process to the area defined by the opening 128. The isotropic etching process also removes the dummy gate dielectric 97 underlying the opening 128, as illustrated in FIGS. 10A and 10B.

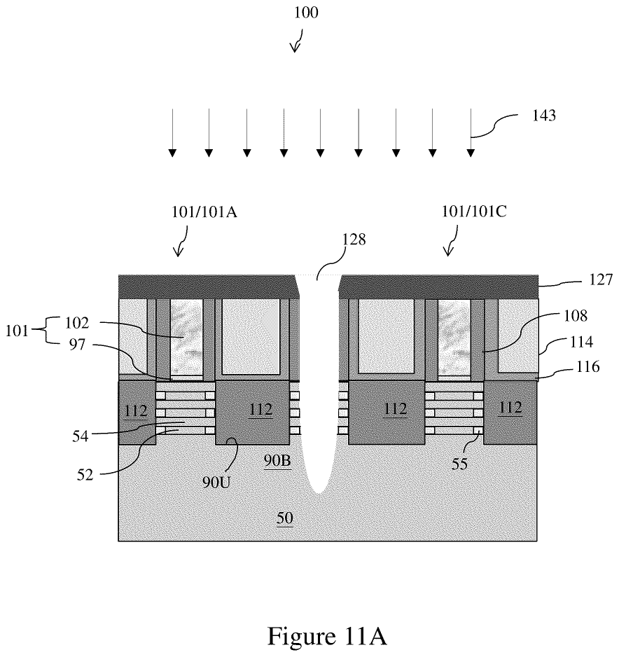

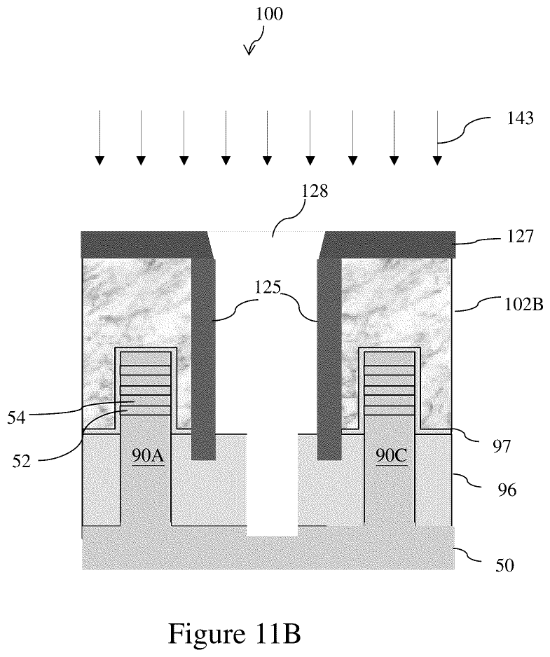

Next, in FIGS. 11A and 11B, an anisotropic plasma etching process 143 is performed to remove portions of layer stack 92 (which includes the first semiconductor material 52 (e.g., silicon germanium) and the second semiconductor material 54 (e.g., silicon)) underlying the opening 128. In some embodiments, the anisotropic etching process 143 is a plasma dry etching process, and therefore, may be referred to as a plasma dry etching process 143, or an anisotropic plasma etching process 143 hereinafter. The plasma dry etching process 143 may be performed using a gas source comprising HBr, Cl₂, or combinations thereof. In some embodiments, during the plasma dry etching processing 143, other gases, such as O₂, CO₂, or a combination thereof, may be added to the gas source to adjust various aspects of the plasma dry etching process, such as etching rate, etching selectivity, and/or etching profile. Note that in the example of FIG. 11B, a portion of the fin 90B underlying the opening 128 is completely removed, and the opening 128 is therefore extended through the STI regions 96 and into the substrate 50.

Note that the above described method (e.g., an isotropic etching process followed by an anisotropic etching process) to remove the portion of the dummy gate structure 101B is merely a non-limiting example, and other suitable methods may also be used to remove the portion of the dummy gate structure 101B underlying the opening 128, as skilled artisans readily appreciate.

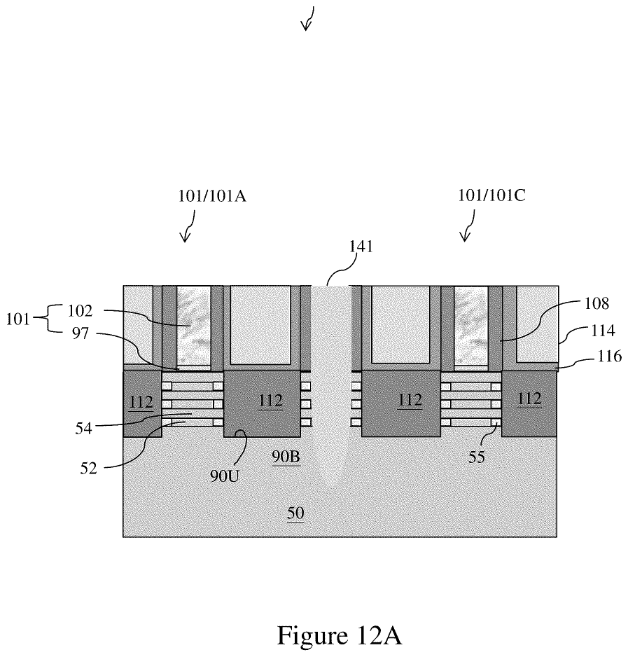

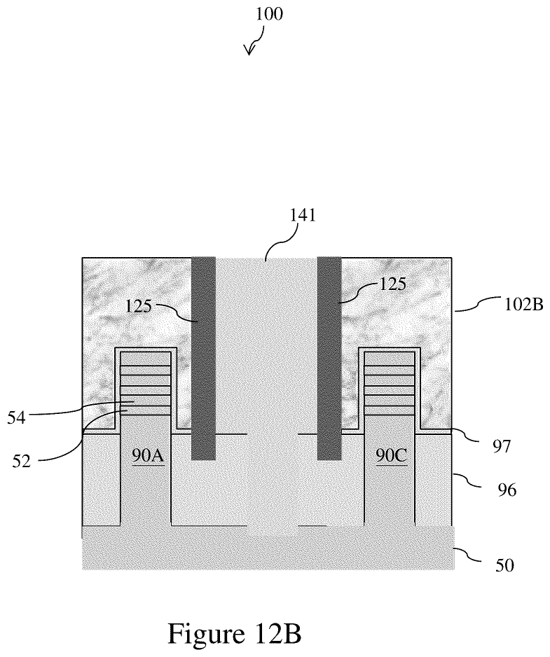

Next, in FIGS. 12A and 12B, a dielectric material 141 is formed to fill the opening 128. The dielectric material 141 may also be formed on the upper surface of the hard mask layer 127. The dielectric material 141 may be, e.g., silicon oxide, silicon nitride, silicon oxynitride, silicon oxycarbonitride, combinations thereof, or multilayers thereof. A suitable formation method, such as CVD, PECVD, ALD, or the like, may be used to form the dielectric material 141. In some embodiments, the dielectric material 141 includes multiple layers of different dielectric materials. In some embodiments, the dielectric material 141 includes multiple layers of the same dielectric material (e.g., SiO or SiN) formed by different formation methods. For example, a layer of the dielectric material may be formed by ALD, then another layer of the same dielectric material may be formed by, e.g., CVD, to fill the opening 128. The dielectric material 141 formed by ALD may be dense and have improved etching resistance, while the dielectric material 141 formed by CVD can be formed quickly to reduce production time and cost. Next, a planarization process, such as CMP, is performed to remove the dielectric material 141 and the hard mask layer 127 from the upper surface of the ILD 114. The remaining portion of the dielectric material 141 forms an isolation structure 141. The isolation structure 141 is also illustrated in the top view of FIG. 14C.

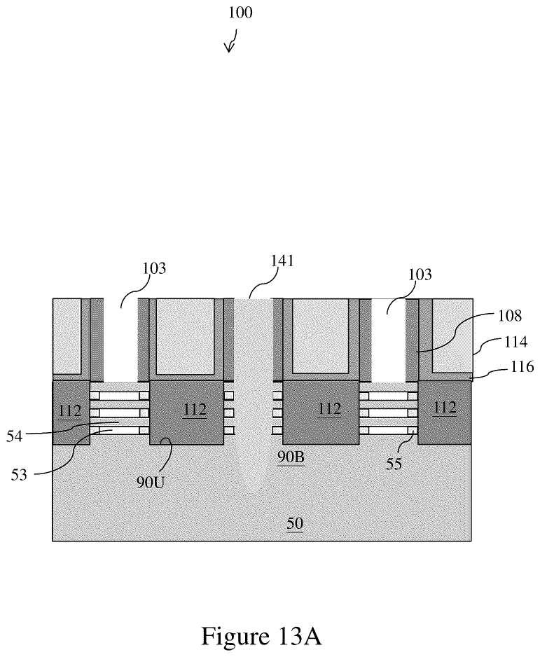

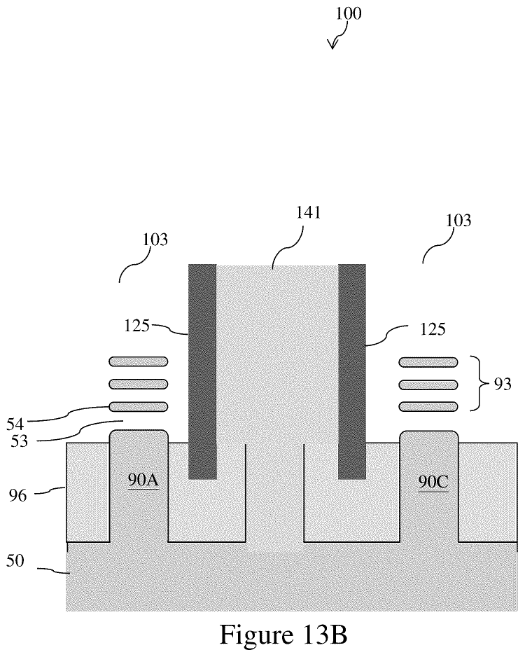

Next, in FIGS. 13A and 13B, the dummy gates 102 and the dummy gate dielectrics 97 are removed, so that recesses 103 (also referred to as gate trenches) are formed in the ILD 114 between respective gate spacers 108. In some embodiments, the dummy gates 102 are removed by an anisotropic dry etching process. For example, the etching process may include a dry etching process using reaction gas(es) that selectively etch the dummy gates 102 without etching the ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. As illustrated in FIGS. 13A and 13B, the recesses 103 expose the channel regions of the NSFET device 100. The channel regions are disposed between neighboring pairs of the epitaxial source/drain regions 112.

Next, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54. Each nanostructure 54 may be referred to as a channel region or a channel layer, and the nanostructures 54 may be collectively referred to as the channel regions 93 or the channel layers 93 of the NSFET device 100 formed. As illustrated in FIGS. 13A and 13B, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

Next, in FIGS. 14A and 14B, the gate spacers 108 are etched back such that the upper surfaces of the gate spacers 108 are recessed below the upper surface of the ILD 114. An anisotropic etching process using an etchant selective to the material of the gate spacers 108 may be performed to etch back the gate spacers 108, as an example. In the illustrated embodiments, the isolation structure 141 is also etched back by the etching process, and a recess 103B is formed over the isolation structure 141.

Next, gate dielectric layers 120 and gate electrodes 122 are formed to form replacement gates. The gate dielectric layers 120 are deposited conformally in the recesses 103, such as on the top surfaces and the sidewalls of the semiconductor fin 90, on sidewalls of the gate spacers 108, and on sidewalls of the CESL 116 exposed to the recesses 103. The gate dielectric layers 120 may also be formed on the top surface of the ILD 114. Notably, the gate dielectric layers 120 are formed to wrap around the nanostructures 54. In accordance with some embodiments, the gate dielectric layers 120 comprise silicon oxide, silicon nitride, or multilayers thereof. In some embodiments, the gate dielectric layers 120 are formed of a high-K dielectric material, and in these embodiments, the gate dielectric layers 120 may have a K value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, the gate electrodes 122 are deposited over and around the gate dielectric layers 120, and fill the remaining portions of the recesses 103. The gate electrodes 122 may include a metal-containing material such as TiN, TiO, TaN, TaC, Co, Ru, Al, W, combinations thereof, or multi-layers thereof. For example, although a single layer gate electrode 122 is illustrated, the gate electrode 122 may comprise any number of liner layers (e.g., barrier layers), any number of work function tuning layers, and a fill metal material. After the filling of the gate electrodes 122, a planarization process, such as a CMP, may be performed to remove the excess portions of the gate dielectric layers 120 and the material of the gate electrodes 122, which excess portions are over the top surface of the ILD 114. The remaining portions of material of the gate electrodes 122 and the gate dielectric layers 120 thus form replacement gate structures of the resulting NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Next, the gate structures 123 are etched back, e.g., by a suitable etching process. The etching process (also referred to as gate structure etching back process) may be, e.g., a wet etching process, a dry etching process, combinations thereof, or the like. The etching process may use an etchant that selectively removes (e.g., etches) the materials of the gate structures 123. An etching mask may be used to cover areas not intended for removal (e.g., covering the ILD 114 and the CESL 116) during the gate structure etching back process. In the illustrated embodiments, after the gate structures 123 are etched back, the upper sidewalls of the CESL 116 are exposed.

In some embodiments, the gate structure etching back process is controlled such that after the gate structure etching back process is finished, the upper surfaces of the gate structures 123 are at about the same level with the upper surfaces of the recessed gate spacers 108. In some embodiments, the gate structure 123 covers (e.g., extends along) a first portion of the upper surface of a respective gate spacer 108 while exposing a second portion of the upper surface of the respective gate spacer 108, as illustrated by the gate structure 123A in FIG. 14A. In some embodiments, the gate structure 123 completely covers the upper surface of a respective gate spacer 108, as illustrated by the gate structure 123C in FIG. 14A. The upper portion of the gate structure 123A (or 123C) in FIG. 14A is therefore wider than the lower portion of the gate structure 123A (or 123C). For example, the lower portion of the gate structure 123A (or 123C) has straight (e.g., vertical) sidewalls, and the upper portion of the gate structure 123A (or 123C) has curved sidewalls that bend away from the gate structure. In some embodiments, the upper surface of the gate structure 123 is level with the upper surface of a respective gate spacer 108, and therefore, does not cover the upper surface of the respective gate spacer 108, as illustrated by the gate structures 123B1 and 123B2 in FIG. 14C and discussed hereinafter. Note that the gate structure etching back process also removes the gate dielectric layers 120 and the gate electrodes 122 formed in the recess 103B (e.g., formed on the recessed isolation structure 141), such that the upper surface of the isolation structure 141 and the upper surfaces of the gate spacers 108 around the isolation structure 141 are exposed, in some embodiments.

FIG. 14B illustrates a gate structure 123B1 formed over the fin 90A and a gate structure 123B2 formed over the fin 90C. The gate structures 123B1 and 123B2 are separated by the isolation structure 141 and the dielectric plugs 125.

FIG. 14C illustrates the top view (e.g., a plan view) of the NSFET device 100 in FIG. 14A. For simplicity, not all features of the NSFET device 100 are illustrated in FIG. 14C. For example, FIG. 14C only shows the fins 90A, 90B, 90C (may be collectively referred to as fins 90), the gate structures 123A, 123B1, 123B2, and 123C (may be collectively referred to as gate structures 123), gate spacers 108 around the sidewalls of the gate structures 123, the dielectric plugs 125, and the isolation structure 141. Note that in FIG. 14C, a distance OF1, measured between an exterior sidewall of a gate spacer 108 and a corresponding sidewall of the gate structure 123A, is smaller than the distance OF2 measured between an exterior sidewall of a gate spacer 108 and a corresponding sidewall of the gate structure 123B1 (or 123B2), because the gate structure 123A covers a portion of the upper surface of the gate spacer 108 (see FIG. 14A), and in contrast, the gate structure 123B1 does not cover the upper surface of the corresponding gate spacer 108. In the top view of FIG. 14C, sidewalls of the gate structure 123C overlap (e.g., completely overlap) the sidewalls of the corresponding gate spacers 108, because the gate structure 123C completely covers the upper surface of the corresponding gate spacer 108 (see FIG. 14A).

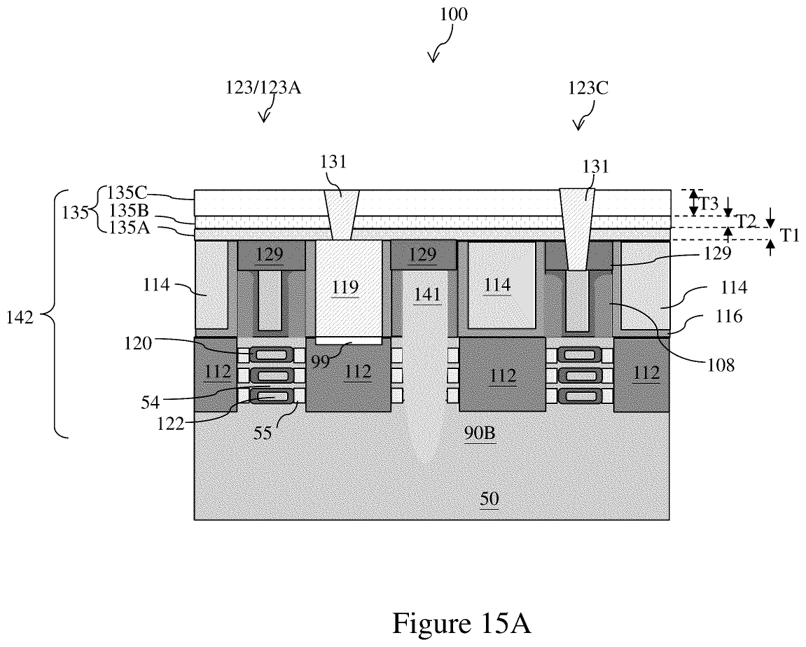

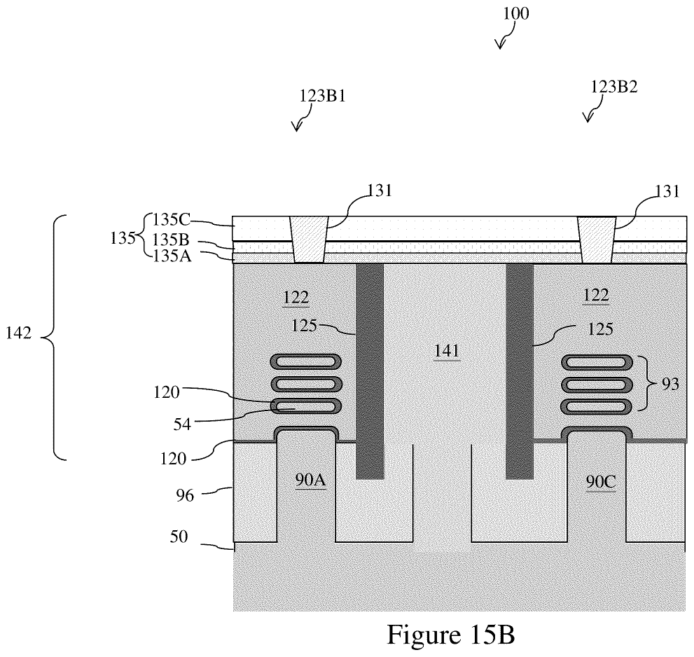

Next, in FIGS. 15A and 15B, gate masks 129 are formed over the gate structures 123 and the isolation structure 141, and source/drain contact plugs 119 (also referred to as source/drain contacts) are formed to electrically couple to the source/drain regions 112. In the illustrated embodiments, the source/drain contact plugs 119 are formed in a self-aligned manner, and fill the spaces between opposing sidewalls of the CESL 116.

In some embodiments, the gate masks 129 are formed by filling the openings in the ILD 114 and over the recessed gate structures 123 and the recessed isolation structure 141 with a dielectric material, then performing a planarization process to remove the dielectric material disposed outside the recesses. The remaining portions of the dielectric material in the recesses form the gate masks 129.

In some embodiments, one or more anisotropic etching processes are performed to remove portions of the ILD 114 and portions of the CESL 116 that are disposed over the source/drain regions 112 to form source/drain contact openings and to expose the source/drain regions 112. The source/drain contact plugs 119 may be formed by filling the source/drain contact openings with an electrically conductive material(s), such as tungsten, although other suitable materials such as aluminum, copper, tungsten nitride, ruthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings. The number and the location of the source/drain contact plugs 119 illustrated in the figures are illustrative and non-limiting, as skilled artisans readily appreciate.

In the illustrated embodiments, silicide regions 99 are formed on the source/drain regions 112 before the source/drain contact openings are filled to form the source/drain contact plugs 119. In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, a middle contact etch stop layer (MCESL) 135 is formed over the ILD 114, the gate structures 123, the gate masks 129, the CESL 116, and the gate spacers 108. In the illustrated embodiments, the MCESL 135 has a multi-layered structure, and includes a layer of a dielectric material 135A (also referred to as a dielectric layer 135A), a layer of a dielectric material 135B (also referred to as a dielectric layer 135B), and a layer of a dielectric material 135C (also referred to as a dielectric layer 135C) formed successively on the ILD 114, the gate structures 123, the gate masks 129, the CESL 116, and the gate spacers 108. Compared with a reference MCESL design, where the reference MCESL design includes a silicon nitride layer and an overlying silicon oxide layer, the disclosed MCESL achieves lower dielectric constant, less oxygen penetration, better photolithography quality, and better device performance (e.g., faster switching speed and/or lower power consumption). Details are discussed hereinafter.

In some embodiments, the dielectric material 135A has a higher density and/or a higher dielectric constant than the dielectric materials 135B and 135C. The dielectric material 135A may be a nitride material (e.g., a nitrogen-containing dielectric material) such as silicon oxycarbonitride (SiOCN) or silicon carbonitride (SiCN) formed by a suitable formation method, such as CVD, ALD, or the like, as an example. In an embodiment where the dielectric material 135A is silicon oxycarbonitride, the dielectric constant of the dielectric material 135A is between about 4.4 and about 4.6. In some embodiments, the dielectric material 135A has a slower etch rate than the dielectric materials 135B and 135C, and therefore, performs most of the etch stopping function of the MCESL 135. A thickness of the dielectric material 135A may be between about 1 nm and about 3 nm, as an example.

In some embodiments, the dielectric material 135B has a lower dielectric constant than the dielectric materials 135A and 135C, and therefore, helps to reduce the overall dielectric constant of the MCESL 135, which in turn reduces the parasitic capacitance (e.g., gate-source parasitic capacitance) of the device formed. The dielectric material 135B may be, e.g., silicon oxycarbide (SiOC) formed by a suitable formation method, such as CVD, ALD, or the like, as an example. In an embodiment where the dielectric material 135B is silicon oxycarbide, the dielectric constant of the dielectric material 135B is between about 2.9 and about 3.1. In some embodiments, the dielectric material 135B has a slower etch rate than the dielectric material 135C, and therefore, also performs some of the etch stopping function of the MCESL 135. A thickness of the dielectric material 135B may be between about 2 nm and about 8 nm, as an example.

In some embodiments, the dielectric material 135B has a lower atomic percentage of oxygen than the dielectric material 135C, and therefore, functions as a buffer layer to reduce the downward diffusion of oxygen from the dielectric material 135C into the gate structures 123 (also referred to as oxygen penetration). Since oxygen penetration may degrade the resistance-capacitance (RC) performance of the device formed (e.g., causing slower switching speed and/or higher power consumption), the dielectric material 135B helps to reduce or avoid oxygen penetration, thus improving the performance of the device formed.

In some embodiments, the dielectric material 135C has a higher hardness and/or density than the dielectric material 135B. In some embodiments, the dielectric material 135C is silicon oxide (SiO) formed by a suitable formation method, such as CVD, ALD, or the like, as an example. In an embodiment where the dielectric material 135C is silicon oxide, the dielectric constant of the dielectric material 135C is between about 3.9 and about 4.2, such as 4.0. A thickness of the dielectric material 135C may be between about 4 nm and about 10 nm, as an example. In some embodiments, the dielectric material 135C is beneficial for improving the quality (e.g., accuracy) of photolithography for the MCESL 135. For example, when silicon oxide is used as the dielectric material 135C, the dielectric material 135C is able to form a dielectric layer with a flat upper surface, which is beneficial for photolithography. In addition, silicon oxide may provide excellent adhesion with the photoresist formed on the dielectric material 135C for photolithography. Furthermore, silicon oxide provides sufficient hardness to allow for the use of a single layer of photoresist as the mask layer for the photolithography.

In some embodiments, the thicknesses of the dielectric layers 135A, 135B, and 135C are adjusted to achieve different performance priorities and/or balance between the different performance criteria, such as etch stopping capability, low dielectric constant, ability to stop oxygen penetration, and high photolithography quality. In an embodiment where the performance priority is to achieve low overall dielectric constant for the MCESL 135, the thickness T₂ of the dielectric layer 135B is larger than the thickness T₃ of the dielectric layer 135C, and the thickness T₃ of the dielectric layer 135C is larger than the thickness T₁ of the dielectric layer 135A. In an embodiment where the performance priority is to achieve high photolithography quality, the thickness T₃ of the dielectric layer 135C is larger than the thickness T₂ of the dielectric layer 135B and the thickness T₁ of the dielectric layer 135A, and the thickness T₂ of the dielectric layer 135B may be larger than, equal to, or smaller than that the thickness T₁ of the dielectric layer 135A, depending on other performance considerations.

Next, vias 131 are formed to extend through the MCESL 135, and to electrically couple to the source/drain contact plugs 119 and the gate electrodes 122. The vias 131 may be formed by forming via openings that extend through the MCESL 135, or through the MCESL 135 and the gate masks 129, then filling the via openings with an electrically conductive material. The electrically conductive material may be a low resistance metal, such as tungsten or molybdenum, as examples. In some embodiments, the vias 131 have a barrier-less structure, and are formed by filling the via openings with a single metal material without forming barrier layer(s) along the sidewalls of the via openings. The barrier-less structure may be advantageous for advanced semiconductor processing nodes, due to the difficulty with filling small openings.

In FIGS. 15A and 15B, the layers of the NSFET device 100 disposed between upper portions of the fins 90 and the MCESL 135 are collectively referred to as the device layer 142 of the NSFET device 100.

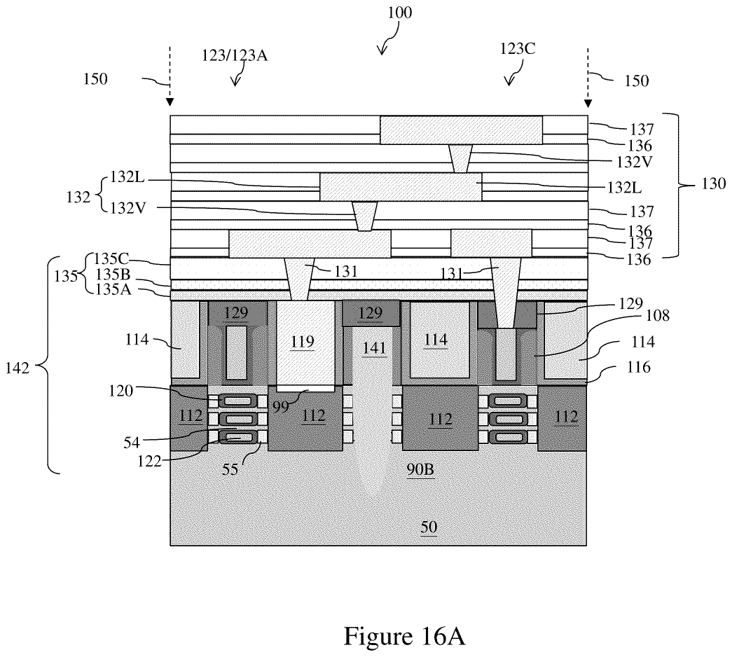

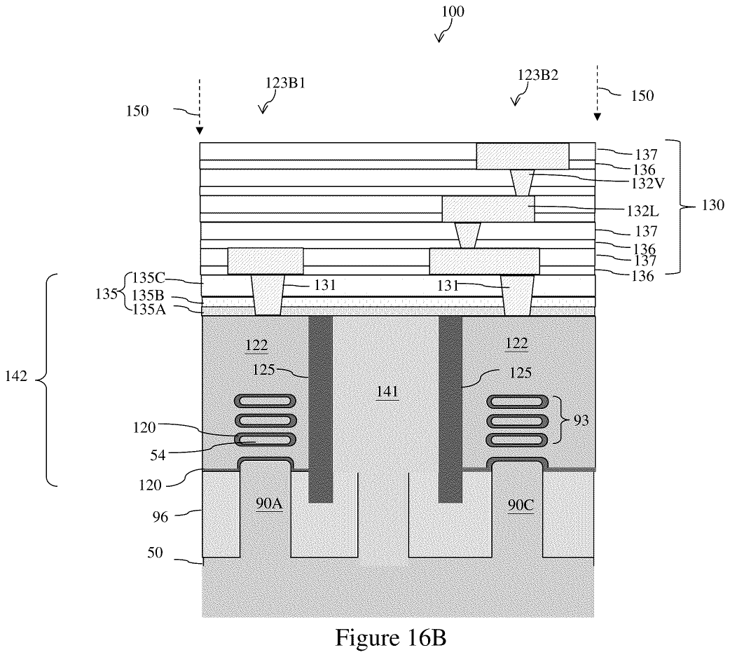

Next, in FIGS. 16A and 16B, an interconnect structure 130 is formed over the MCESL 135. The interconnect structure 130 includes etch stop layers (ESLs) 136 and dielectric layers 137 interleaved with each other. In the example of FIGS. 16A and 16B, each dielectric layer 137 is disposed over a respective ESL 136. Electrically conductive features 132, such as conductive lines 132L and vias 132V, are formed in the dielectric layers 137 and the ESLs 136. The interconnect structure 130 interconnects the electrical components (e.g., transistors) formed in or on the substrate 50 to form functional circuits.

The ESLs 136 and the dielectric layers 137 may be formed of any suitable dielectric materials. In an embodiment, the ESLs 136 are formed of silicon nitride, and the dielectric layers 137 are formed of silicon oxide. A suitable formation method, such as CVD, PECVD, ALD, combinations thereof, or the like, may be used to form the ESLs 136 (or the dielectric layers 137). The conductive features 132 (e.g., metal lines and vias) may be formed using, e.g., damascene processes. In the example of FIGS. 16A and 16B, due to the use of damascene process, the via 132V (or the conductive line 132L) has an upper surface flush with an upper surface of a respective dielectric layer 137, and has a lower surface flush with a lower surface of a respective ESL 136. The conductive features 132 may include diffusion barriers and a metal-containing material (e.g., copper) over the diffusion barriers. The diffusion barriers (may also be referred to as liner layers) may be, e.g., Ta, Ti, TaN, TiN, or the like. The metal-containing material may be, e.g., Cu, Co, Ru, Mo, or the like. In some embodiments, the topmost conductive features 132 (e.g., the conductive features 132 in a topmost dielectric layer 137 distal from the device layer 142) may include conductive features (e.g., bonding pads, or metal patterns used for bonding) used for bonding with another semiconductor device.

Additional processing may be performed to finish the fabrication of the NSFET device 100, as skilled artisans readily appreciate. For example, a dicing process may be performed along dicing regions indicated by the dashed lines 150 in FIGS. 16A and 16B to separate multiple NSFET devices 100 formed on a same wafer (e.g., substrate 50) into individual NSFET devices 100. Details are not discussed here.

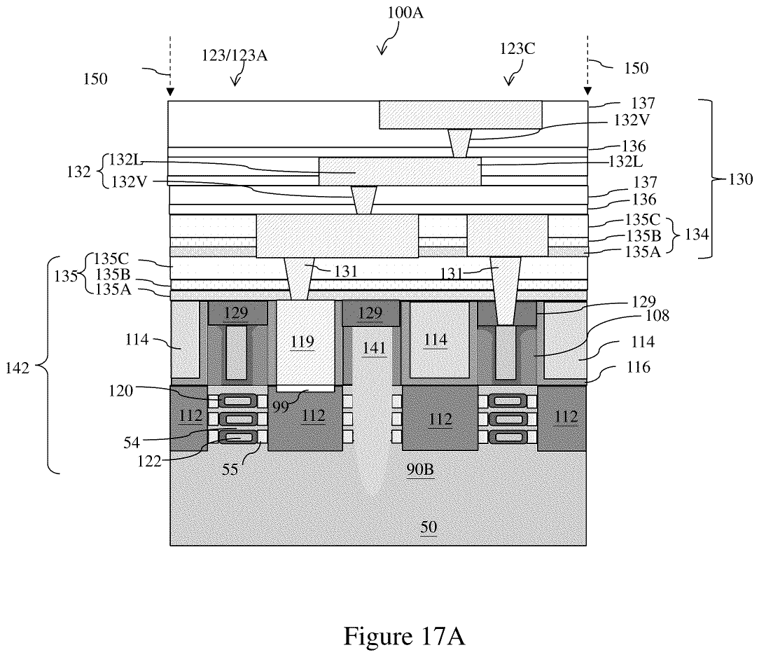

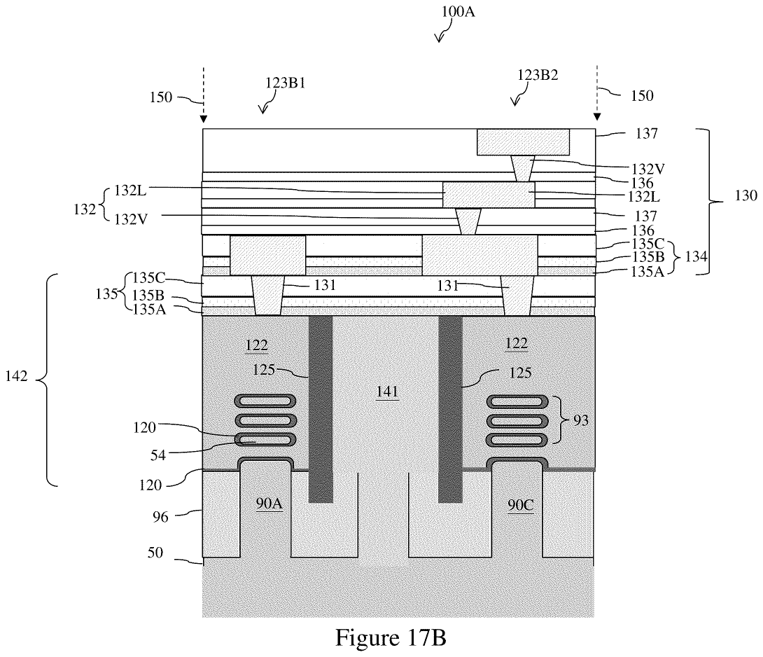

FIGS. 17A and 17B illustrate cross-sectional views of an NSFET device 100A, in accordance with another embodiment. The NSFET device 100A is similar to the NSFET device 100, but with the lowermost ESL 136 and the lowermost dielectric layer 137 of the interconnect structure 130 in FIGS. 16A and 16B replaced by a multi-layered dielectric structure 134, which multi-layered dielectric structure 134 has a same structure formed by the same materials as the MCESL 135. In other words, the first three dielectric layers in the interconnect structure 130 of the NSFET device 100A are the dielectric layers 135A, 135B, and 135C formed successively on the MCESL 135. Conductive features, such as conductive lines 132L, are formed in the multi-layered dielectric structure 134 of the interconnect structure 130. After the multi-layered dielectric structure 134 is formed, alternating layers of the ESL 136 and the dielectric layer 137 are formed over the multi-layered dielectric structure 134, and alternating layers of vias 132V and conductive lines 132L are formed in the ESLs 136 and the dielectric layers 137. For ease of discussion, the multi-layered dielectric structure 134 may also be referred to as dielectric structure 134.

In some embodiments, the overall dielectric constant of the multi-layered dielectric structure 134 is smaller than that of a dual-layered structure comprising the ESL 136 (e.g., SiN) and the dielectric layer 137 (e.g., SiO). Therefore, replacing the lowermost ESL 136 and the lowermost dielectric layer 137 with the multi-layered dielectric structure 134 reduces the overall dielectric constant of the interconnect structure 130, thus improving device performance (e.g., faster switching speed and/or lower device power consumption). The ESLs 136 and the dielectric layers 137 of the interconnect structure 130 disposed over the multi-layered dielectric structure 134 are further away from the gate structures 123, and replacing them with the multi-layered dielectric structure 134 may result in negligible performance improvement at increased cost. Therefore, only the lowermost ESL 136 and the lowermost dielectric layer 137 of the interconnect structure 130 are replaced with the multi-layered dielectric structure 134, in some embodiments.

In the example of FIGS. 17A and 17B, both damascene and dual-damascene processes are used to form the conductive features of the interconnect structure 130. For example, the topmost vias 132V and the topmost conductive lines 132L are formed by a dual-damascene process, while the underlying vias 132V and conductive lines 132L are formed by damascene processes. As a result, the upper surface of the topmost conductive line 132L is flush with the upper surface of the topmost dielectric layer 137, and the lower surface of the topmost conductive line 132L is further from the device layer 142 than the lower surface of the topmost dielectric layer 137. In addition, the upper surface of the topmost via 132V is closer to the device layer 142 than the upper surface of the topmost dielectric layer 137, and a lower surface of the topmost via 132V is flush with the lower surface of the topmost ESL 136. While the topmost conductive lines 132L and the topmost vias 132V in the interconnect structure 130 of FIGS. 17A and 17B are formed by dual-damascene, skilled artisans will readily appreciate that damascene or dual-damascene may be used for any layers of conductive features in the interconnect structure 130, depending on various performance criteria and design considerations.

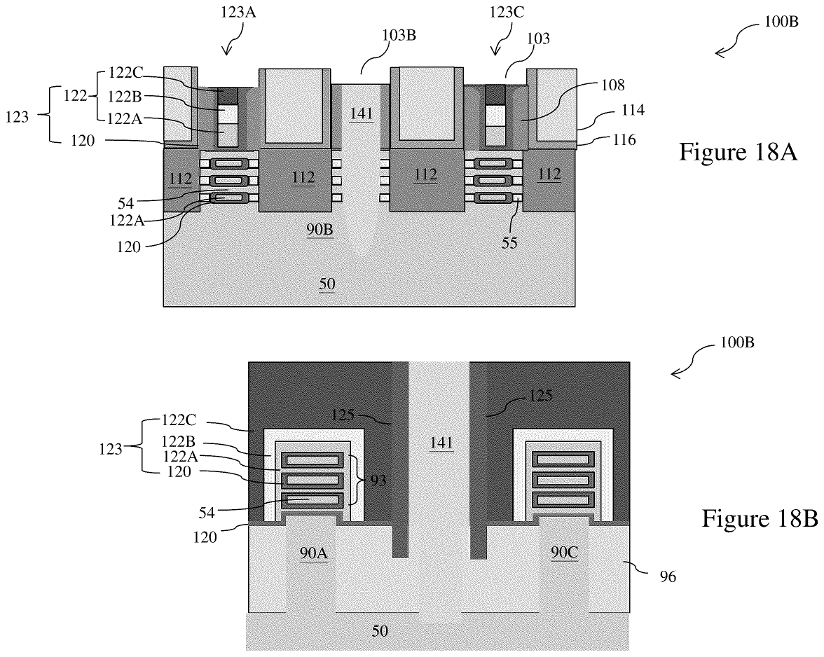

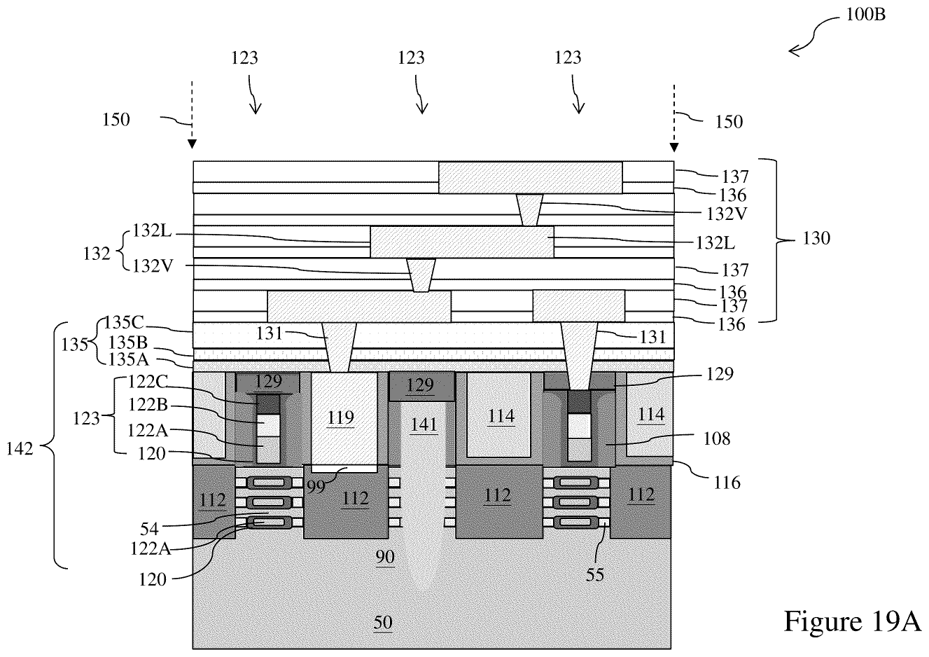

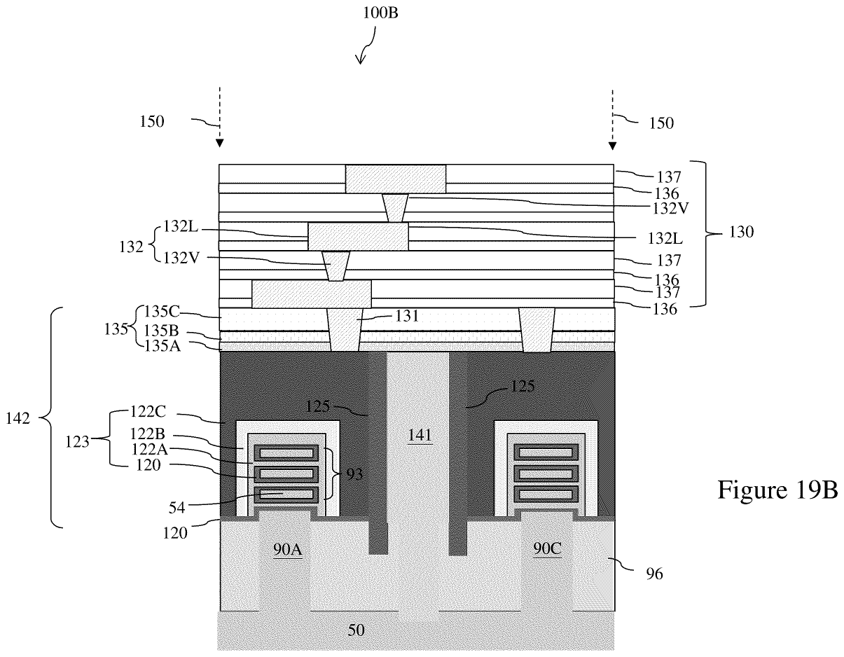

FIGS. 18A, 18B, 19A, and 19B illustrate cross-sectional views of an NSFET device 100B at various stages of manufacturing, in accordance with another embodiment. The NSFET device 100B is similar to the NSFET device 100, but with the gate electrode 122 formed differently. The processing stage of FIGS. 18A and 18B follows the processing stage of FIGS. 13A and 13B.

In FIGS. 18A and 18B, the gate spacers 108 are etched back by an etching process such that the gate spacers 108 are recessed from the upper surface of the ILD 114. The isolation structure 141 is also etched back by the etching process. Details are the same as or similar to those discussed above for the NSFET device 100, thus not repeated.

Next, gate dielectric material 120 and gate electrode materials 122 (e.g., 122A, 122B, and 122C) are formed in the recesses 103 to form replacement gate structures 123. In some embodiments, the gate dielectric material 120 is formed of the same or similar material using the same or similar formation method as discussed above for the NSFET device 100, thus details are not repeated.

Next, a gate electrode material 122A is deposited over and around the gate dielectric material 120. In the illustrated embodiments, the gate electrode material 122A fills (e.g., completely fills) the gaps 53 between vertically adjacent nanostructures 54 and between the lowermost nanostructures 54 and the fins 90. The gate electrode material 122A may be a metal or a metal-containing material such as Co, Ru, Al, W, TiN, or TaN, formed by a suitable formation process such as PVD, CVD, ALD, or the like.

Next, a gate electrode material 122B is formed around the nanostructures 54 and around the gate electrode material 122A. The gate electrode material 122B is a different material from the gate electrode material 122A, and may be chosen from the candidate materials listed above for the gate electrode material 122A. The gate electrode material 122B may be formed by a same or similar formation method as the gate electrode material 122A.

Next, a gate electrode material 122C is formed around the nanostructures 54 and around the gate electrode materials 122A and 122B. The gate electrode material 122C fills (e.g., completely fills) the remaining portions of the recesses 103. The gate electrode material 122C is a different material from the gate electrode materials 122A and 122B, and may be chosen from the candidate materials listed above for the gate electrode material 122A. The gate electrode material 122C may be formed by a same or similar formation method as the gate electrode material 122A. The gate electrode materials 122A, 122B, and 122C may be collectively referred to as the gate electrode material 122 of the NSFET device 100B.

After the gate electrode material 122 is formed, a planarization process, such as CMP, may be performed to remove excess portions of the gate dielectric material 120 and the gate electrode material 122, which excess portions are over the top surface of the ILD 114. The remaining portions of the gate electrode material 122 and the gate dielectric material 120 thus form the gate electrodes 122 and the gate dielectric layers 120 of the replacement gate structures 123 of the resulting NSFET device 100B, respectively.

Next, the gate structure etching back process discussed above is performed to recess the gate structures 123. The gate structure etching back process also removes the gate dielectric material 120 and the gate electrode material 122 formed in the recess 103B (e.g., on the upper surface of the recessed isolation structure 141). In some embodiments, the gate structure etching back process is controlled such that after the gate structure etching back process is finished, the upper surfaces of the gate structures 123 are at about the same level with the upper surfaces of the recessed gate spacers 108. In some embodiments, the gate structure 123 covers (e.g., extends along) a first portion of the upper surface of a respective gate spacer 108 while exposing a second portion of the upper surface of the respective gate spacer 108, as illustrated by the gate structure 123A in FIG. 18A. In some embodiments, the gate structure 123 completely covers the upper surface of a respective gate spacer 108, as illustrated by the gate structure 123C in FIG. 18A. The upper portion of the gate structure 123A (or 123C) in FIG. 18A is therefore wider than the lower portion of the gate structure 123A (or 123C). In some embodiments, the upper surface of the gate structure 123 is level with the upper surface of a respective gate spacer 108, and therefore, does not cover the upper surface of the respective gate spacer 108.

In the example of FIG. 18A, the cross-sections of the gate electrode materials 122A and 122B disposed between respective gate spacers 108 have rectangular shapes instead of U-shapes, such as the U-shape of the gate dielectric layer 120. The rectangular shaped cross-section of the gate electrode material 122A (or 122B) may be due to, e.g., the formation method used for forming the gate electrode material 122A (or 122B), or an etching process performed after the gate electrode material 122A (or 122B) is deposited in the recesses 103, where the etching process removes portions of the deposited gate electrode material 122A (or 122B) that are disposed along sidewalls of the gate spacers 108 above the rectangular shaped portions.

In some embodiments, the replacement gate structures 123 of FIGS. 18A and 18B use the different materials of the gate electrode materials 122A, 122B, and 122C to tune the work function of the replacement gate structures 123. In other words, unlike conventional design without the presently disclosed structures, the replacement gate structures 123 of FIGS. 18A and 18B do not need to form work function layers between the gate dielectric layers 120 and the gate electrodes 122. As feature size continues to shrink in advanced semiconductor manufacturing, it is increasingly difficult to line sidewalls and bottoms of gate trenches 103 with multiple layers of work function materials. The disclosed replacement gate structure 123 obviates the need to form work function layers in the gate trenches 103, thus simplifying the manufacturing process and avoiding potential defects caused by the difficulties in forming the work function layers in small recesses.

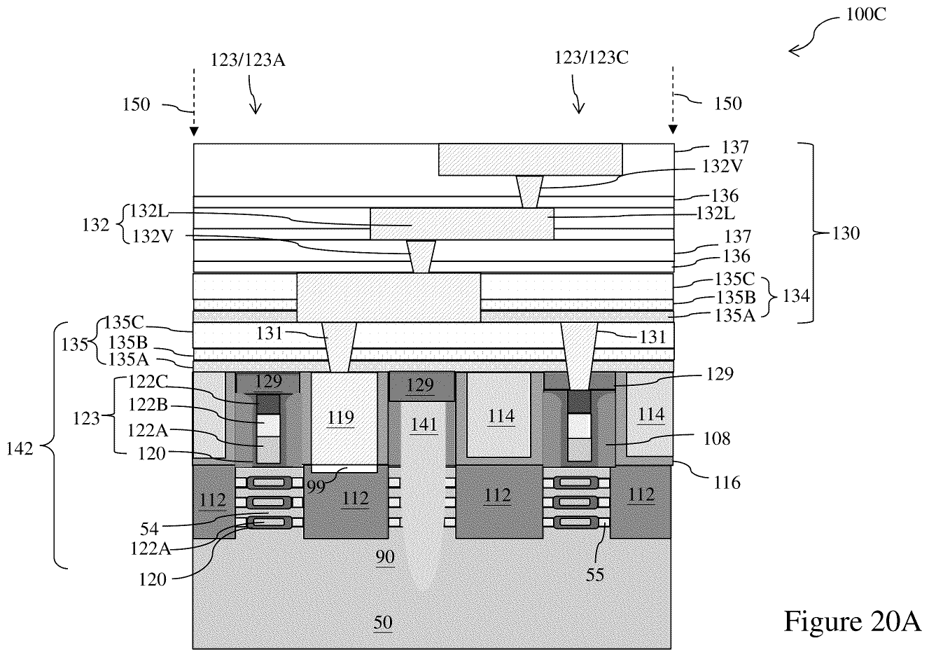

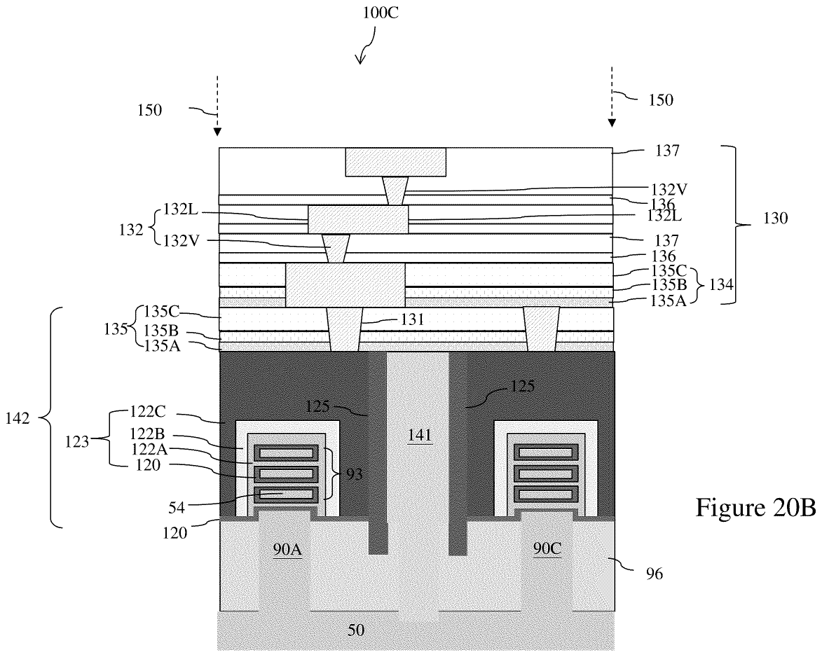

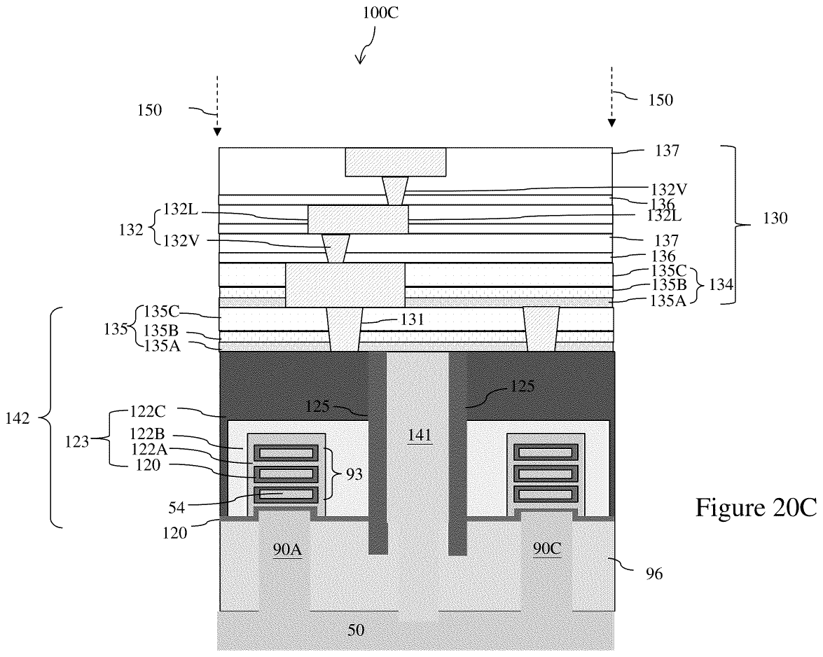

Although the gate electrode 122 in FIGS. 18A and 18B is illustrated as including three different materials (e.g., 122A, 122B, and 122C), skilled artisans will readily appreciate that the gate electrode 122 may include less than three (e.g., one or two) different materials, or may include more than three different materials. In addition, in FIG. 18B, portions of the gate electrode material 122B over two adjacent fins 90 are separated from each other. This is, of course, merely a non-limiting example. The gate electrode material 122B over two adjacent fins 90 may merge together, see, e.g., FIG. 20C. These and other variations are fully intended to be included within the scope of the present disclosure.

Next, in FIGS. 19A and 19B, the gate masks 129 are formed over the gate structures 123 and the isolation structure 141, and the source/drain contact plugs 119 are formed to electrically couple to the source/drain regions 112. Silicide regions 99 may be formed between the source/drain regions 112 and the source/drain contact plugs 119. Next, the MCESL 135 with the multi-layered structure is formed over the ILD 114, the gate structures 123, the gate masks 129, the CESL 116, and the gate spacers 108. Next, the interconnect structure 130 is formed over the MCESL 135. Details are the same as or similar to those discussed above for the NSFET device 100, thus not repeated.

FIGS. 20A, 20B, and 20C illustrate cross-sectional views of an NSFET device 100C, in accordance with another embodiment. The NSFET device 100C is similar to the NSFET device 100B, but with the lowermost ESL 136 and the lowermost dielectric layer 137 of the interconnect structure 130 in FIGS. 19A and 19B replaced by the multi-layered dielectric structure 134. In addition, the topmost vias 132V and the topmost conductive lines 132L of the interconnect structure 130 are formed by a dual-damascene process, while the underlying vias 132V and conductive lines 132L are formed by damascene processes. Details are the same as or similar to those discussed above for the NSFET device 100B, thus not repeated.

In FIG. 20B, the gate electrode material 122B around channel regions 93 over two adjacent fins 90 are separated from each other, and are spaced apart from the dielectric plugs 125. This is, of course, merely a non-limiting example. FIG. 20C illustrates another example where the gate electrode material 122B contacts (e.g., physically contacts) the dielectric plugs 125. Although not shown, the gate electrode material 122B around channel regions 93 over the fin 90A and another immediately adjacent fin 90 (e.g., to the left of the fin 90A, not shown) may merge together. These and other variations are fully intended to be included within the scope of the present disclosure.

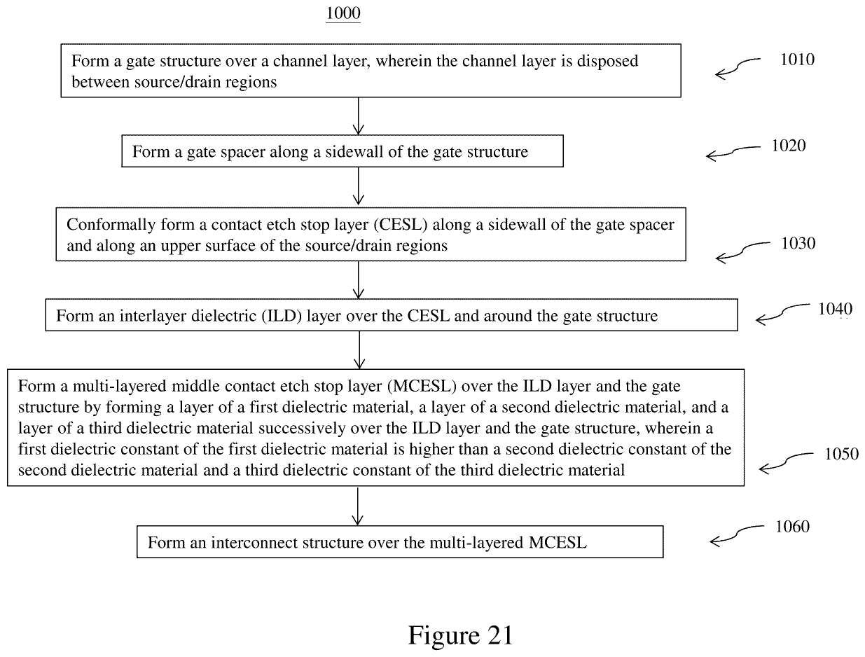

FIG. 21 illustrates a flow chart of a method 1000 of forming a semiconductor device, in accordance with some embodiments. It should be understood that the embodiment method shown in FIG. 21 is merely an example of many possible embodiment methods. One of ordinary skill in the art would recognize many variations, alternatives, and modifications. For example, various steps as illustrated in FIG. 21 may be added, removed, replaced, rearranged, or repeated.

Referring to FIG. 21, at block 1010, a gate structure is formed over a channel layer, wherein the channel layer is disposed between source/drain regions. At block 1020, a gate spacer is formed along a sidewall of the gate structure. At block 1030, a contact etch stop layer (CESL) is conformally formed along a sidewall of the gate spacer and along an upper surface of the source/drain regions. At block 1040, an interlayer dielectric (ILD) layer is formed over the CESL and around the gate structure. At block 1050, a multi-layered middle contact etch stop layer (MCESL) is formed over the ILD layer and the gate structure by forming a layer of a first dielectric material, a layer of a second dielectric material, and a layer of a third dielectric material successively over the ILD layer and the gate structure, wherein a first dielectric constant of the first dielectric material is higher than a second dielectric constant of the second dielectric material and a third dielectric constant of the third dielectric material. At block 1060, an interconnect structure is formed over the multi-layered MCESL.

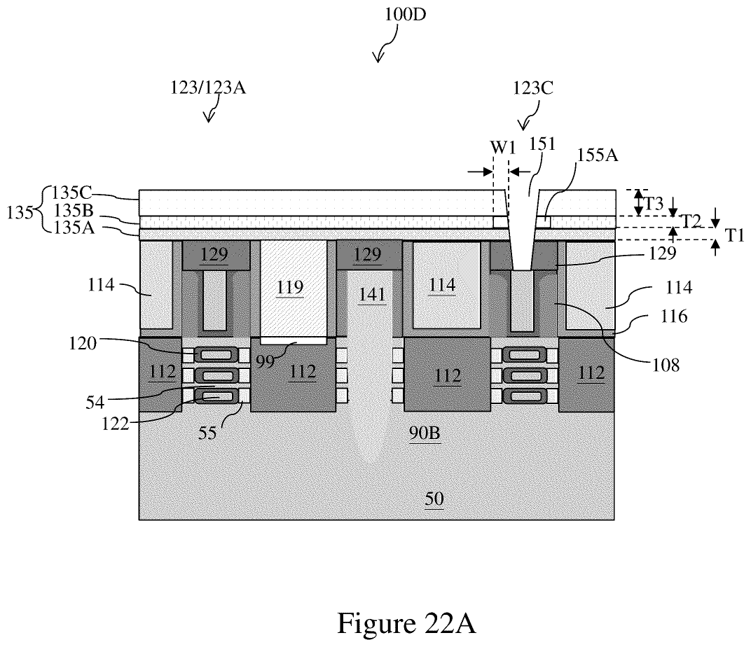

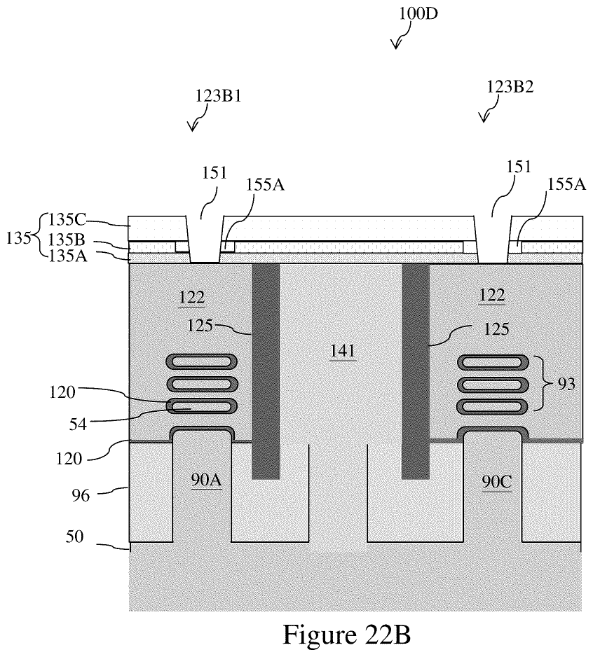

FIGS. 22A, 22B, 23A, 23B, 24, 25, 26A, and 26B illustrate cross-sectional views of an NSFET device 100D at various stages of manufacturing, in accordance with another embodiment. The processing of FIGS. 22A and 22B follows that illustrated in FIGS. 14A-14C. In other words, FIGS. 2, 3A, 3B, 4A, 4B, 5A, 5B, 5C, 6A, 6B, 6C, 7A, 7B, 7C, 8A, 8B, 9A, 9B, 10A, 10B, 11A, 11B, 12A, 12B, 13A, 13B, 14A, 14B, 14C, 22A, 22B, 23A, 23B, 24, 25, 26A, and 26B illustrate the processing steps for the NSFET device 100D.

In FIGS. 22A and 22B, the gate masks 129 are formed over the gate structures 123 and the isolation structure 141, and source/drain contact plugs 119 are formed to electrically couple to the source/drain regions 112. In some embodiments, silicon regions 99 are formed on the source/drain regions 112 before the source/drain contact plugs 119 are formed. Next, the middle contact etch stop layer (MCESL) 135 is formed over the ILD 114, the gate structures 123, the gate masks 129, the CESL 116, and the gate spacers 108. Details are the same as or similar to those discussed above with references to FIGS. 15A and 15B, thus not repeated here.

Next, via openings 151 are formed in the MCESL 135 over the gate structures 123 (e.g., 123C). The via openings 151 are formed to extend through the MCESL 135 and the gate mask 129, and to expose the respective underlying gate structures 123. In some embodiments, the via openings 151 are formed by performing an anisotropic etching process using an etching mask (e.g., a patterned photoresist layer). The anisotropic etching process may be an anisotropic plasma etching process performed using a gas source comprising carbon fluoride (e.g. CFₓ), oxygen (e.g., O₂), carbon monoxide (e.g., CO), and argon (e.g., Ar), as an example.

After the via openings 151 are formed, the etching mask for forming the via openings 151 is removed by performing an ashing process. In some embodiments, the ashing process is a plasma process (also referred to as a plasma ashing process) performed using a gas source comprising nitrogen (e.g., N₂) and hydrogen (e.g., H₂). Besides removing the etching mask, the plasma ashing process also turns (e.g., converts, transforms) portions of the dielectric material 135B (e.g., SiOCN) exposed to the via openings 151 into dielectric regions 155A, which dielectric regions 155A have a different material composition than the dielectric material 135B. In addition, the plasma ashing process also prepares the surfaces of the via openings 151 for the subsequent deposition of a conductive material (e.g., tungsten) in the via openings 151. Details are discussed hereinafter.

In some embodiments, the plasma used in the plasma ashing process contains energetic species (e.g., ions, radicals, electrons) that provide sufficient energy to break the weak Si—CH₃ bonds in the dielectric material 135B (e.g., SiOC). Active species in the plasma react with carbon species (e.g.,—CH3) of the dielectric material 135B to form volatile product(s), which is then evacuated from the process chamber. Therefore, the plasma ashing process is also said to consume the carbon in the dielectric material 135B. For example, H• radicals in the plasma may react with the —CH3 group to form CH₄. As another example, NH• radicals and NH₂• radicals may react with carbon species to form certain volatile product(s). As yet another example, N• radicals may form volatile nitrogen-carbon compounds with carbon species. In some embodiments, after the carbon species react with the active species in the plasma, the remaining silicon-oxygen network in the dielectric material 135B restructures, with oxygen filling the sites previously occupied by carbon, thereby transforming (e.g., converting) portion of the dielectric material 135B exposed to (e.g., adjacent to) the via openings 151 into the dielectric regions 155A illustrated in FIGS. 22A and 22B. In the illustrated embodiments, the dielectric regions 155A comprise silicon oxide, which is different from the dielectric material 135B (e.g., silicon oxycarbide).

In the example of FIGS. 22A and 22B, the dielectric regions 155A have a same thickness as the dielectric material 135B, such that the upper surface and the lower surface of each dielectric region 155A are flush (e.g., level) with the upper surface and the lower surface of the dielectric material 135B, respectively. A width W1 of the dielectric region 155A, measured between a sidewall of the dielectric region 155A and a respective sidewall of the via opening 151, may be between about 4 nm and about 5 nm, as an example. The sidewalls of the dielectric region 155A laterally distal from the via opening 151 are illustrated as straight sidewalls as a non-limiting example, the sidewalls of the dielectric region 155A may be curved (e.g., concave or convex) and/or may have an irregular shape. These and other variations are fully intended to be included within the scope of the present disclosure.

In the illustrated embodiment, the dielectric regions 155A comprise a different dielectric material (e.g., SiO) than the dielectric material 135B (e.g., SiOC). Note that other portions of the dielectric material 135B, such as portions further away from the via openings 151 than the dielectric regions 155A, remain unchanged after the plasma ashing process, because those portions are not in contact with the plasma of the plasma ashing process. In the example of FIGS. 22A and 22B, the dielectric regions 155A are formed in the dielectric material 135B, but not in the dielectric materials 135A and 135C of the MCESL 135, because the energy of the plasma ashing process is not high enough to break the chemical bonds in the dielectric materials 135A and 135C, in some embodiments.

In some embodiments, the plasma of the N₂ gas and the H₂ gas (referred to as N₂/H₂ plasma) used in the plasma ashing process also functions to treat surfaces (e.g., the sidewalls and the bottoms) of the via openings 151, and may be considered as a surface treatment process. In some embodiments, the N₂/H₂ plasma creates surface terminations on the sidewalls and the bottoms of the via openings 151 that are conducive to the subsequent deposition of a conductive material (e.g., tungsten) in the via openings 151. For example, hydroxyl (—OH) groups may be formed when H• radicals react with exposed Si—O bonds. In addition, amino groups (—NH₂) may be formed by nitrogen plasma species reacting with the surface material. In some embodiments, hydroxyl group and amino group provide improved surface energy matching between dielectric material and metal, and provide active sites for tungsten precursor molecules to anchor and nucleate during the subsequent deposition of tungsten in the via openings 151. In some embodiments, chemical bonding between the surface terminations and tungsten precursors creates stronger interfacial adhesion, which reduces the risk of delamination during subsequent processing steps.

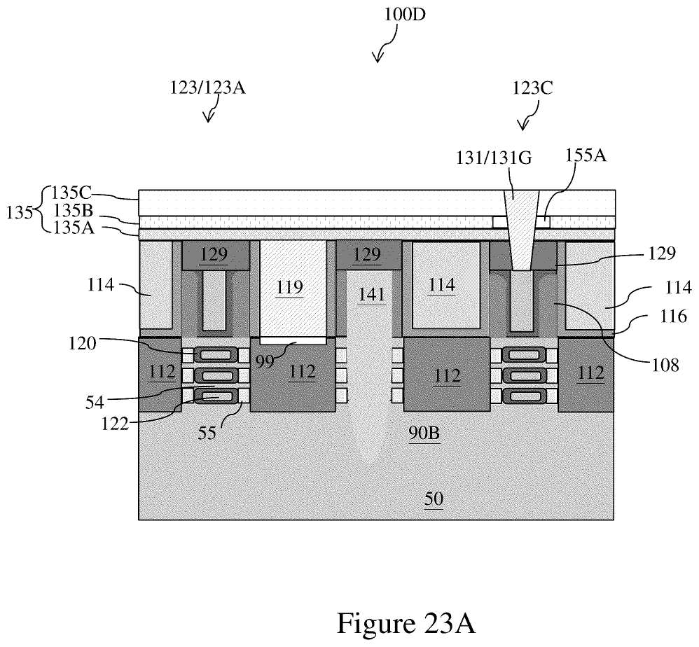

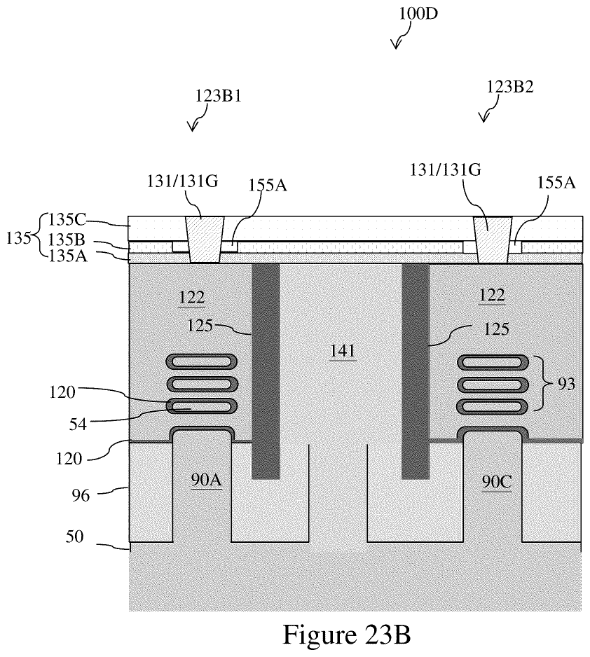

Next, in FIGS. 23A and 23B, vias 131G are formed in the via openings 151 by filling the via openings 151 with an electrically conductive material (e.g., tungsten). In some embodiments, a CVD process is performed using a tungsten-containing precursor (e.g., WCl₄) to form tungsten in the via openings 151. A planarization process, such as CMP, may be performed next to remove excess portions of tungsten from the upper surface of the MCESL 135, and the remaining portions of tungsten in the via openings 151 form the vias 131G. The vias 131G are electrically coupled to the gate structure 123, and may also be referred to as gate contacts 131G, or gate vias 131G. As illustrated in FIGS. 23A and 23B, each of the dielectric regions 155A embedded in the dielectric layer 135B contacts and extends along sidewalls of a respective via 131G.

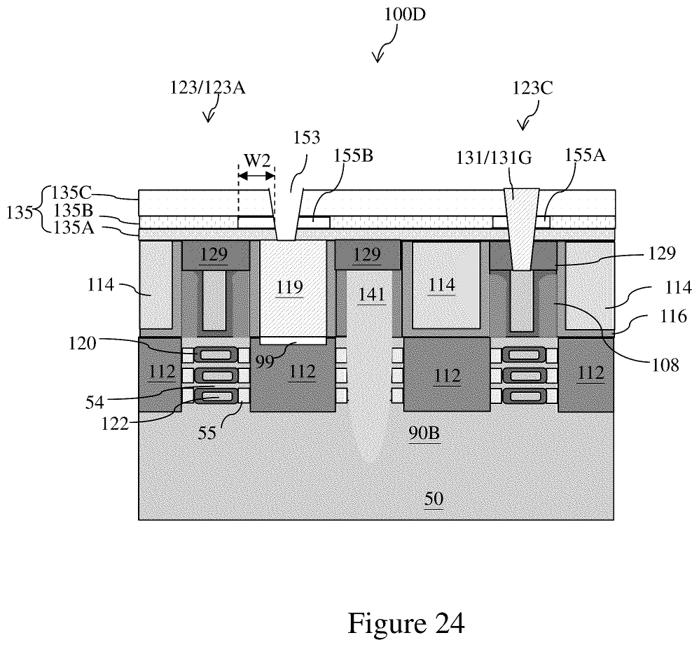

Next, in FIG. 24, via openings 153 are formed in the MCESL 135 over the source/drain contacts 119. FIG. 24 illustrates the cross-sectional view along the same cross-section of FIG. 23A. For simplicity, the cross-sectional view along the cross-section of FIG. 23B is not illustrated for the processing step of FIG. 24 (and 25), since such as a cross-sectional view may the same as or similar to that of FIG. 23B.

In FIG. 24, the via openings 153 are formed to extend through the MCESL 135 to expose the respective underlying source/drain contacts 119. In some embodiments, the via opening 153 are formed by performing an anisotropic etching process using an etching mask (e.g., a patterned photoresist layer). The anisotropic etching process may be an anisotropic plasma etching process performed using a gas source comprising carbon fluoride (e.g. CFₓ), oxygen (e.g., O₂), carbon monoxide (e.g., CO), and argon (e.g., Ar), as an example.

After the via openings 153 are formed, the etching mask for forming the via openings 153 is removed by performing an ashing process. In some embodiments, the ashing process is a plasma ashing process performed using a gas source comprising oxygen (e.g., O₂). After the plasma ashing process is finished, a pre-treatment process is performed to clean the via openings 153 and to prepare the surfaces of the via openings 153 for the subsequent deposition of a conductive material (e.g., molybdenum) in the via openings 153. The plasma ashing process and the pre-treatment process turn (e.g., converts, transforms) portions of the dielectric material 135B (e.g., SiOC) exposed to the via openings 153 into dielectric regions 155B, which dielectric regions 155B have a different material composition than the dielectric material 135B. Details are discussed hereinafter.

In some embodiments, the plasma of O₂ gas (referred to as O₂ plasma) used in the plasma ashing process contains highly reactive species, such as O• radicals and oxygen ions (e.g., O⁺, O₂⁺). These species attack (e.g., break) the weak Si—CH₃ bonds in the dielectric material 135B through oxidization reactions. The —CH3 groups may react with O• radicals and form volatile products such as CO and H₂O, as an example. As another example, through direct oxidization by O₂, the Si—CH₃ bonds are broken, and the —CH3 groups may react with the reactive species in the O₂ plasma to form volatile product such as CO₂.

In some embodiments, the pre-treatment process is a plasma process performed with a gas source comprising oxygen (O₂) and hydrogen (H₂). The gas source is ignited into plasma, which includes O₂ plasma and the plasma of H₂ gas (also referred to as H₂ plasma). The O₂ plasma and the H₂ plasma are used to treat the surfaces of the via openings 153. In addition, the O₂ plasma used in the plasma ashing process, together with the O₂ plasma and the H₂ plasma used in the pre-treatment process, convert portions of the dielectric material 135B exposed to the via openings 153 into dielectric regions 155B. More details are discussed hereinafter.

The pre-treatment process creates surface terminations on the sidewalls and the bottoms of the via openings 153 that are conducive to the subsequent deposition of a conductive material (e.g., Mo) in the via openings 153. For example, hydroxyl (—OH) groups may be formed at the surfaces of the via openings 153, which provide anchoring sites for Mo precursors and are conducive to forming strong chemical bonding between the surface —OH groups and the Mo material deposited. The H₂ plasma may also provide some —H surface terminations that can be beneficial for certain Mo precursors. In addition, the H₂/O₂ plasma treatment creates a mildly reducing surface environment, which may facilitate the reduction of Mo precursors to metallic Mo. The combination of O₂ plasma and H₂ plasma creates a balance between hydrophilic condition and a reducing surface condition. Furthermore, the H₂/O₂ plasma treatment also removes organic contaminants that may outgas during Mo deposition.

Besides functioning as a surface treatment process, the pre-treatment process using the O₂ plasma and the H₂ plasma also functions to convert portions of the dielectric layer 135B exposed to the via openings 153 into the dielectric regions 155B. In some embodiments, the O₂ plasma and the H₂ plasma used in the pre-treatment process break the Si—CH₃ bonds in the dielectric material 135B, and the reactive species in the O₂ plasma and the H₂ plasma react with the carbon species (e.g., —CH3 groups) of the dielectric material 135B to form volatile product(s), which is evacuated from the process chamber. The chemical reactions between the reactive species of the O₂ plasma and the-CH3 groups have been discussed above for the plasma ashing processing performed using O2 plasma, thus not repeated. In addition, reactive species in the H₂ plasma, such as H• radicals, may react with the —CH3 groups to form volatile product such as CH₄. In some embodiments, after the carbon species in the exposed portions of the dielectric material 135B react with the active species in the O₂ plasma and the H₂ plasma to form volatile products, the remaining silicon-oxygen network in the dielectric material 135B restructures, with oxygen filling the sites previously occupied by carbon, thereby transforming (e.g., converting) portions of the dielectric material 135B exposed to (e.g., adjacent to) the via openings 153 into the dielectric regions 155B in FIG. 24. In the illustrated embodiments, the dielectric regions 155B comprise a different material (e.g., silicon oxide) than the dielectric material 135B (e.g., silicon oxycarbide).

In the illustrated embodiment of FIG. 24, the dielectric regions 155B have a same thickness as the dielectric material 135B, such that the upper surface and the lower surface of each dielectric region 155B are flush (e.g., level) with the upper surface and the lower surface of the dielectric material 135B, respectively. A width W2 of the dielectric region 155B, measured between a sidewall of the dielectric region 155B and a respective sidewall of the via opening 153, may be between about 20 nm and about 30 nm, as an example. The dielectric regions 155B are wider than the dielectric regions 155A, which may due to both the plasma ashing process and the pre-treatment process converting the exposed portions of the dielectric material 135B into the dielectric regions 155B. The sidewalls of the dielectric region 155B laterally distal from the via opening 153 are illustrated as straight sidewalls as a non-limiting example, the sidewalls of the dielectric region 155B may be curved (e.g., concave or convex) and/or may have an irregular shape. These and other variations are fully intended to be included within the scope of the present disclosure.

In the illustrated embodiment, the dielectric regions 155B comprise a different dielectric material (e.g., SiO) than the dielectric material 135B (e.g., SiOC). Note that other portions of the dielectric material 135B, such as portions further away from the via openings 153 than the dielectric regions 155B, remain unchanged after the plasma ashing process, because those portions are not in contact with the plasma of the plasma ashing process and the pre-treatment process. In the example of FIG. 24, the dielectric regions 155B are formed in the dielectric material 135B, but not in the dielectric materials 135A and 135C of the MCESL 135, because the energy of the plasma ashing process and the pre-treatment is not high enough to break the chemical bonds in the dielectric materials 135A and 135C, in some embodiments. Note that in the illustrated embodiments, the dielectric regions 155A and 155B have a same material composition (e.g., both comprising a same dielectric material SiO).

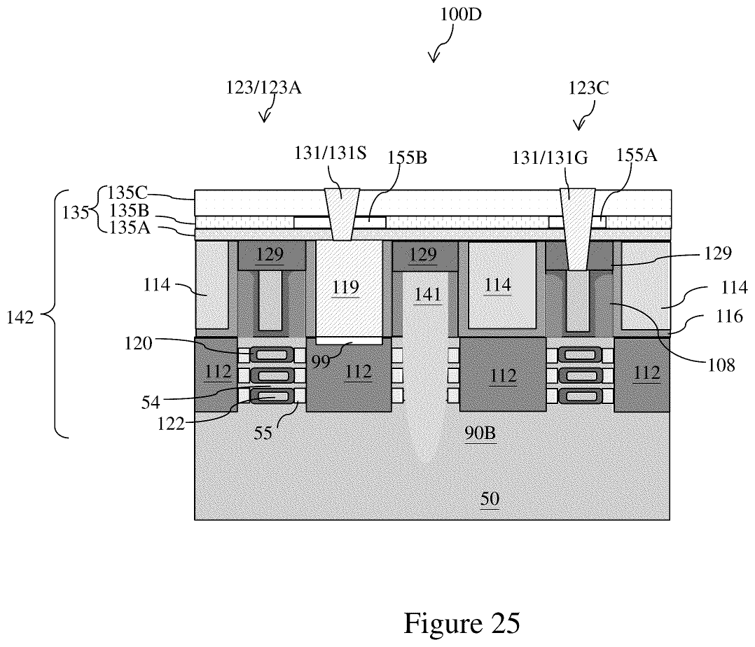

Next, in FIG. 25, vias 131S are formed by filling the via openings 153 with an electrically conductive material (e.g., molybdenum). In some embodiments, a CVD process is performed using a molybdenum-containing precursor (e.g., MoCl₅) to form molybdenum in the via openings 153. A planarization process, such as CMP, may be performed next to remove excess portions of molybdenum from the upper surface of the MCESL 135, and the remaining portions of molybdenum in the via openings 153 form the vias 131S. The vias 131S are electrically coupled to the source/drain contacts 119, and may also be referred to as source/drain via 131S. The source/drain vias 131S and the gate vias 131G may be collectively referred to as vias 131. As illustrated in FIG. 25, each of the dielectric regions 155B embedded in the dielectric layer 135B contacts and extends along sidewalls of a respective via 131S.

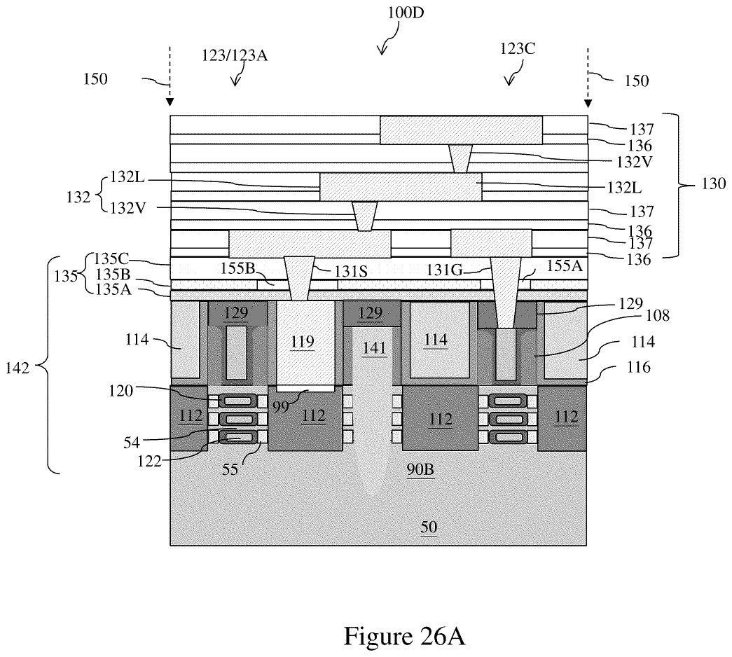

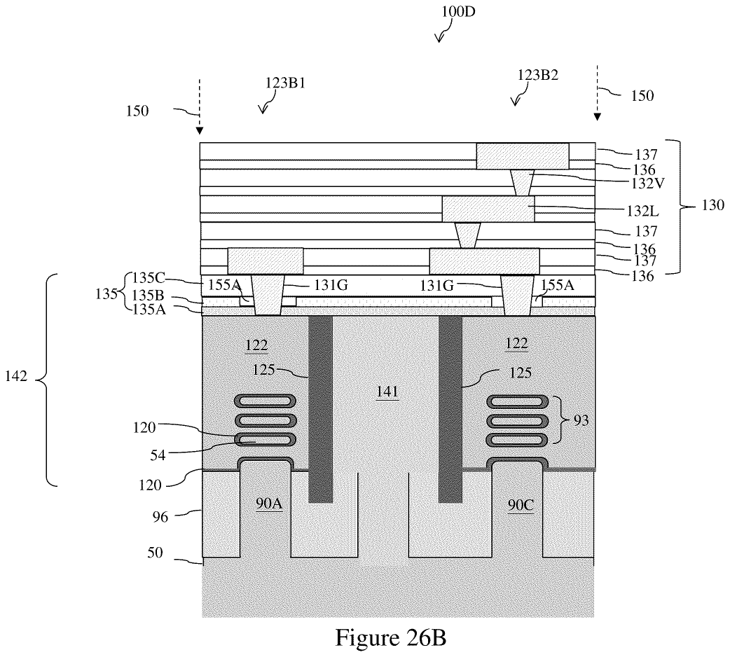

Next, in FIGS. 26A and 26B, the interconnect structure 130 is formed over the MCESL 135. The interconnect structure 130 includes etch stop layers (ESLs) 136 and dielectric layers 137 interleaved with each other. In the example of FIGS. 26A and 26B, each dielectric layer 137 is disposed over a respective ESL 136. Electrically conductive features 132, such as conductive lines 132L and vias 132V, are formed in the dielectric layers 137 and the ESLs 136. The materials and the formation methods for the interconnect structure 130 are discussed above, thus details are not repeated.

In some embodiments, the ESLs 136 have a larger dielectric constant than the dielectric layers 137, and the dielectric constant of the dielectric layers 137 is smaller than that of the gate dielectric layer 120. In some embodiments, the thicknesses of the dielectric layers 137 of the interconnect structure 130 increase along a vertical direction pointing away from the substrate 50. For example, a first dielectric layer 137, which is further away from the substrate 50 than a second dielectric layer 137, may have a first thickness that is larger than a second thickness of the second dielectric layer 137. As a result, the conducive features 132 embedded in the dielectric layers 137 may also have increasing thicknesses along the vertical direction pointing away from the substrate 50. For example, a first conductive feature (e.g., a first conducive line) farther away from the substrate 50 may be thicker than a second conductive feature (e.g., a second conductive line) closer to the substrate 50. In some embodiments, the conductive features 132 include alternating layers of conductive lines 132L and vias 132V. In some embodiments, two adjacent layers of conductive lines 132L extends along two directions that are perpendicular to each other, and are interconnected by the layer of vias 132V interposed in-between.

Additional processing may be performed to finish the fabrication of the NSFET device 100D, as skilled artisans readily appreciate. For example, a dicing process may be performed along dicing regions indicated by the dashed lines 150 in FIGS. 26A and 26B to separate multiple NSFET devices 100D formed on a same wafer (e.g., substrate 50) into individual NSFET devices 100D. Details are not discussed here.

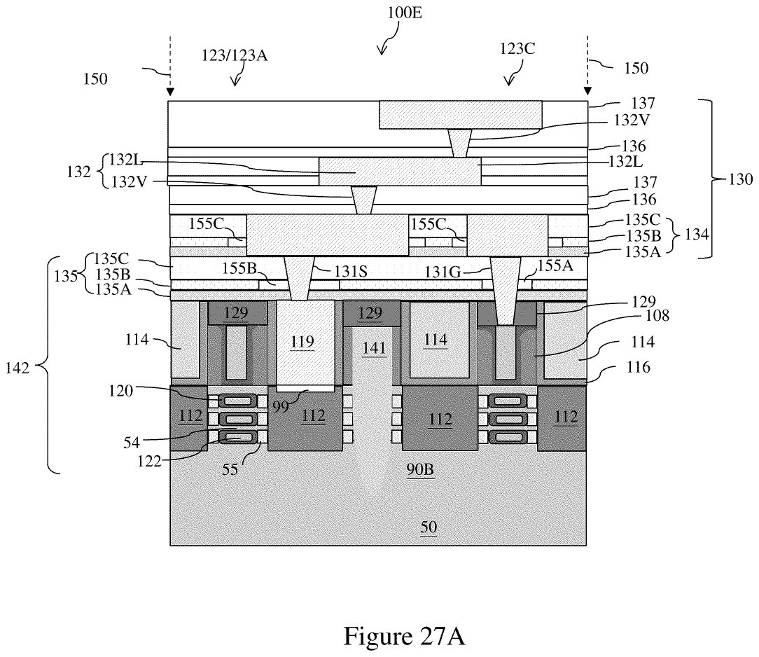

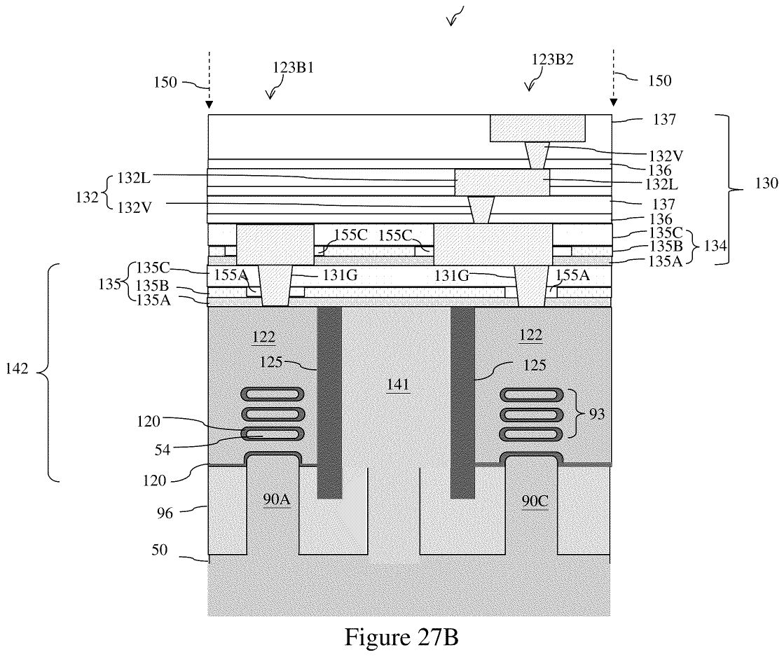

FIGS. 27A and 27B illustrate cross-sectional views of an NSFET device 100E, in accordance with yet another embodiment. The NSFET device 100E is similar to the NSFET device 100D, but with the lowermost ESL 136 and the lowermost dielectric layers 137 of the interconnect structure 130 replaced with a dielectric structure 134, which dielectric structure 134 has the same layered structure as the MCESL 135. In particular, the dielectric structure 134 includes the dielectric layers 135A, 135B, and 135C formed sequentially over the MCESL 135.

In FIGS. 27A and 27B, conductive features 132 (e.g., conductive lines) are formed in the dielectric structure 134. The conductive features 132 may be formed by patterning the dielectric structure 134 with a mask layer (e.g., patterned photoresist) to form openings in the dielectric structure 134, removing the mask layer, and filling the openings in the dielectric structure 134 with an electrically conductive material. In some embodiments, a plasma ashing process is performed to remove the mask layer using, e.g., O₂ plasma and/or other plasma. The O₂ plasma (and/or other plasma used in the plasma ashing process) converts portions of the dielectric layer 135B of the dielectric structure 134 (e.g., portions exposed to the openings in the dielectric structure 134) into dielectric regions 155C, where the dielectric regions 155C comprise a material (e.g., silicon oxide) different from the dielectric layer 135B. Details are the same as or similar to those discussed above, thus not repeated.

Modifications to the disclosed embodiments are possible and are fully intended to be included within the scope of the present disclosure. For example, in the illustrated processing steps for the NSFET device 100D, the vias 131G are formed before the vias 131S. This is, of course, merely a non-limiting example. Skilled artisans will readily appreciate that the vias 131S may be formed before the vias 131G. As another example, while the dielectric regions 155 (e.g., 155A, 155B, and 155C) are illustrated for the NSFET devices 100D and 100E, skilled artisans will readily appreciate that, depending on the processing steps used, dielectric regions same as or similar to the dielectric regions 155 may be formed in the dielectric layer(s) 135B of other disclosed embodiments.

Advantages are achieved by the disclosed embodiments. For example, the disclosed MCESL 135 uses three different dielectric materials with different dielectric constants, different atomic percentages of oxygen, and different hardnesses to achieve a balance between different performance criteria, such as low parasitic capacitance, low oxygen penetration, high photolithography quality, and high device performance (e.g., faster switching speed and/or lower power consumption). Besides the selection of different materials, the thicknesses of the different layers of dielectric materials in the MCESL 135 may also be tuned to achieve different performance priorities. The disclosed MCESL 135 therefore offers many tunable parameters to achieve high performance for the device formed. The multi-layered structure of the MCESL 135 may also be used to replace the lowermost ESL 136 and the lowermost dielectric layer 137 of the interconnect structure 130 to further reduce the parasitic capacitance of the device formed, thus further improving the device performance.

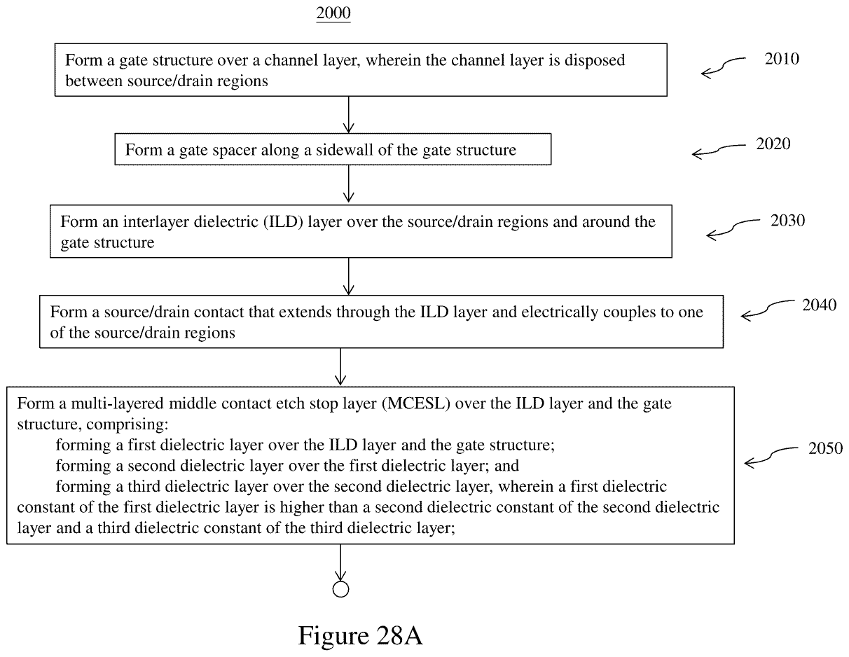

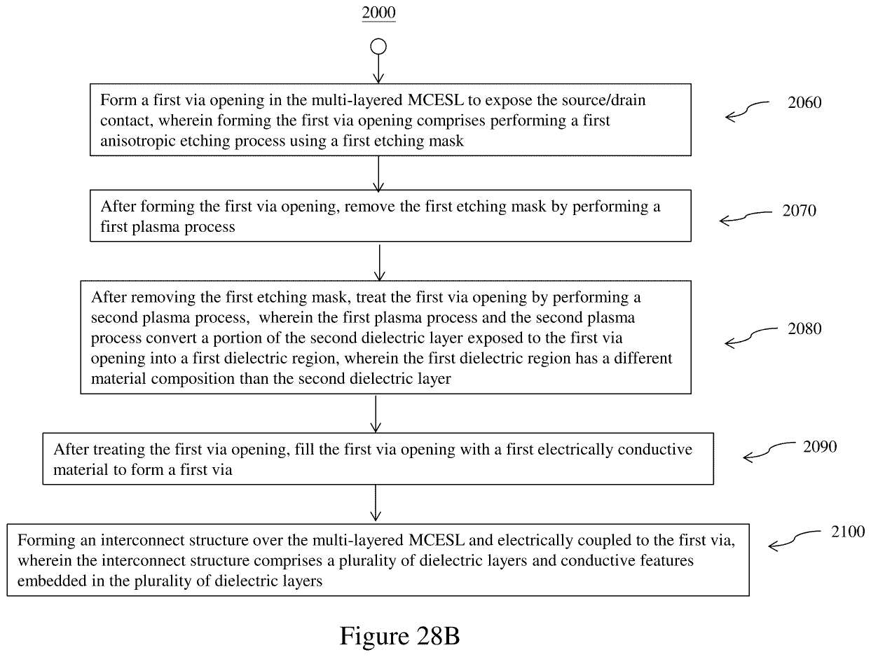

FIGS. 28A and 28B together illustrate a flow chart of a method 2000 of forming a semiconductor device, in accordance with some embodiments. It should be understood that the embodiment method shown in FIGS. 28A and 28B is merely an example of many possible embodiment methods. One of ordinary skill in the art would recognize many variations, alternatives, and modifications. For example, various steps as illustrated in FIGS. 28A and 28B may be added, removed, replaced, rearranged, or repeated.

Referring to FIGS. 28A and 28B, at block 2010, a gate structure is formed over a channel layer, wherein the channel layer is disposed between source/drain regions. At block 2020, a gate spacer is formed along a sidewall of the gate structure. At block 2030, an interlayer dielectric (ILD) layer is formed over the source/drain regions and around the gate structure. At block 2040, a source/drain contact is formed that extends through the ILD layer and electrically couples to one of the source/drain regions. At block 2050, a multi-layered middle contact etch stop layer (MCESL) is formed over the ILD layer and the gate structure, comprising: forming a first dielectric layer over the ILD layer and the gate structure; forming a second dielectric layer over the first dielectric layer; and forming a third dielectric layer over the second dielectric layer, wherein a first dielectric constant of the first dielectric layer is higher than a second dielectric constant of the second dielectric layer and a third dielectric constant of the third dielectric layer. At block 2060, a first via opening is formed in the multi-layered MCESL to expose the source/drain contact, wherein forming the first via opening comprises performing a first anisotropic etching process using a first etching mask. At block 2070, after forming the first via opening, the first etching mask is removed by performing a first plasma process. At block 2080, after removing the first etching mask, the first via opening is treated by performing a second plasma process, wherein the first plasma process and the second plasma process convert a portion of the second dielectric layer exposed to the first via opening into a first dielectric region, wherein the first dielectric region has a different material composition than the second dielectric layer. At block 2090, after treating the first via opening, the first via opening is filled with a first electrically conductive material to form a first via. At block 2100, an interconnect structure is formed over the multi-layered MCESL and electrically coupled to the first via, wherein the interconnect structure comprises a plurality of dielectric layers and conductive features embedded in the plurality of dielectric layers.

In an embodiment, a semiconductor device includes: source/drain regions; a channel layer between the source/drain regions; a gate structure over the channel layer; a gate spacer along a sidewall of the gate structure; a contact etch stop layer (CESL) along a sidewall of the gate spacer and along an upper surface of the source/drain regions; an interlayer dielectric (ILD) layer over the CESL and around the gate structure; a source/drain contact extending through the ILD layer and the CESL, and being electrically coupled to one of the source/drain regions; and a middle contact etch stop layer (MCESL) having a multi-layered structure and disposed over the ILD layer and the gate structure, wherein the MCESL comprises: a layer of a first dielectric material having a first dielectric constant; a layer of a second dielectric material over the layer of the first dielectric material, wherein a second dielectric constant of the second dielectric material is smaller than the first dielectric constant; and a layer of a third dielectric material over the layer of the second dielectric material, wherein a third dielectric constant of the third dielectric material is smaller than the first dielectric constant. The semiconductor device further includes: a first via embedded in the MCESL and electrically coupled to the source/drain contact; and an interconnect structure over the MCESL and electrically coupled to the first via. In an embodiment, the second dielectric constant is smaller than the third dielectric constant. In an embodiment, an atomic percentage of oxygen in the second dielectric material is lower than that in the third dielectric material. In an embodiment, a hardness of the third dielectric material is higher than that of the second dielectric material. In an embodiment, the semiconductor device further includes a second via embedded in the MCESL and electrically coupled to the gate structure, wherein the interconnect structure is electrically coupled to the second via. In an embodiment, the interconnect structure comprises: a plurality of etch stop layers (ESLs) and a plurality of dielectric layers, wherein the plurality of ESLs are interleaved with the plurality of dielectric layers; and conductive features embedded in the plurality of ESLs and the plurality of dielectric layers. In an embodiment, the interconnect structure further comprises: a multi-layered dielectric structure between the MCESL and a lowermost ESL of the plurality of ESLs, wherein the lowermost ESL is closer to the gate structure than the plurality of dielectric layers and other ESLs of the plurality of ESLs, wherein the multi-layered dielectric structure and the MCESL have the same multi-layered structure and comprise the same dielectric materials; and a conductive feature embedded in the multi-layered dielectric structure. In an embodiment, the interconnect structure comprises: a third via embedded in a first ESL of the plurality of ESLs and a first dielectric layer of the plurality of dielectric layers, wherein the first dielectric layer is over the first ESL, wherein an upper surface of the third via distal from the gate structure is flush with an upper surface of the first dielectric layer, and a lower surface of the third via is flush with a lower surface of the first ESL; and a first conductive line over and connected with the third via, wherein the first conductive line is embedded in a second ESL of the plurality of ESLs and a second dielectric layer of the plurality of dielectric layers, wherein the second dielectric layer is over the second ESL, wherein an upper surface of the first conductive line distal from the gate structure is flush with an upper surface of the second dielectric layer, and a lower surface of the first conductive line is flush with a lower surface of the second ESL. In an embodiment, the interconnect structure comprises: a fourth via embedded in a third ESL of the plurality of ESLs and a third dielectric layer of the plurality of dielectric layers, wherein the third dielectric layer is over the third ESL, wherein an upper surface of the fourth via distal from the gate structure is closer to the gate structure than an upper surface of the third dielectric layer, and a lower surface of the fourth via is flush with a lower surface of the third ESL; and a second conductive line over and connected to the fourth via, wherein the second conductive line is embedded in the third dielectric layer, wherein an upper surface of the second conductive line distal from the gate structure is flush with the upper surface of the third dielectric layer, and a lower surface of the second conductive line is further from the gate structure than a lower surface of the third dielectric layer. In an embodiment, the semiconductor device further includes a fin, wherein the source/drain regions are disposed over the fin, wherein the gate structure comprises: a gate dielectric material around the channel layer; a first gate electrode material around the gate dielectric material and filling a gap between the channel layer and an upper surface of the fin; and a second gate electrode material around the first gate electrode material. In an embodiment, the first dielectric material is silicon oxycarbonitride or silicon carbonitride, the second dielectric material is silicon oxycarbide, and the third dielectric material is silicon oxide.

In an embodiment, a semiconductor device includes: a channel layer over a substrate and between source/drain regions; a gate structure over the channel layer; a gate spacer along a sidewall of the gate structure; an interlayer dielectric (ILD) layer over the source/drain regions and around the gate structure, wherein the gate spacer and the gate structure are recessed from an upper surface of the ILD layer distal from the substrate, wherein the gate structure extends along at least a portion of an upper surface of the gate spacer distal from the substrate; a source/drain contact extending through the ILD layer and electrically coupled to one of the source/drain regions; and a multi-layered middle contact etch stop layer (MCESL) over the ILD layer and the gate structure, comprising: a first dielectric layer having a first dielectric constant; a second dielectric layer over the first dielectric layer and having a second dielectric constant smaller than the first dielectric constant; and a third dielectric layer over the second dielectric layer and having a third dielectric constant smaller than the first dielectric constant. The semiconductor device further includes an interconnect structure over the multi-layered MCESL. In an embodiment, an atomic concentration of oxygen in the second dielectric layer is lower than that in the third dielectric layer. In an embodiment, the second dielectric constant is smaller than the third dielectric constant. In an embodiment, a third thickness of the third dielectric layer is larger than a second thickness of the second dielectric layer and larger than a first thickness of the first dielectric layer. In an embodiment, a second thickness of the second dielectric layer is larger than a third thickness of the third dielectric layer, wherein the third thickness of the third dielectric layer is larger than a first thickness of the first dielectric layer. In an embodiment, the first dielectric layer is silicon oxycarbonitride or silicon carbonitride, the second dielectric layer is silicon oxycarbide, and the third dielectric layer is silicon oxide.

In an embodiment, a method of forming a semiconductor device includes: forming a gate structure over a channel layer, wherein the channel layer is disposed between source/drain regions; forming a gate spacer along a sidewall of the gate structure; conformally forming a contact etch stop layer (CESL) along a sidewall of the gate spacer and along an upper surface of the source/drain regions; forming an interlayer dielectric (ILD) layer over the CESL and around the gate structure; forming a multi-layered middle contact etch stop layer (MCESL) over the ILD layer and the gate structure by forming a layer of a first dielectric material, a layer of a second dielectric material, and a layer of a third dielectric material successively over the ILD layer and the gate structure, wherein a first dielectric constant of the first dielectric material is higher than a second dielectric constant of the second dielectric material and a third dielectric constant of the third dielectric material; and forming an interconnect structure over the multi-layered MCESL. In an embodiment, the method further comprises: before forming the MCESL, forming a source/drain contact that extends through the ILD layer and the CESL to electrically couple to the source/drain regions; and after forming the MCESL, forming a via in the multi-layered MCESL to electrically couple to the source/drain contact, wherein the interconnect structure is formed to electrically couple to the via. In an embodiment, an atomic concentration of oxygen in the second dielectric material is lower than that in the third dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
source/drain regions;
a channel layer between the source/drain regions;
a gate structure over the channel layer;
a gate spacer along a sidewall of the gate structure;
an interlayer dielectric (ILD) layer over the source/drain regions and around the gate structure;
a source/drain contact extending through the ILD layer and electrically coupled to one of the source/drain regions;
a middle contact etch stop layer (MCESL) disposed over the ILD layer and the gate structure, wherein the MCESL has a multi-layered structure and comprises:
a first dielectric layer having a first dielectric constant;
a second dielectric layer over the first dielectric layer, wherein a second dielectric constant of the second dielectric layer is smaller than the first dielectric constant; and
a third dielectric layer over the second dielectric layer, wherein a third dielectric constant of the third dielectric layer is smaller than the first dielectric constant;
a first via extending through the MCESL and electrically coupled to the source/drain contact;
a first dielectric region embedded in the second dielectric layer and around the first via, wherein a material composition of the first dielectric region is different from that of the second dielectric layer; and
an interconnect structure over the MCESL and electrically coupled to the first via, wherein the interconnect structure comprises:
a plurality of etch stop layers (ESLs) and a plurality of dielectric layers interleaved with the plurality of ESLs; and
first conductive features embedded in the plurality of ESLs and the plurality of dielectric layers, wherein a first one of the first conductive features farther away from the substrate is thicker than a second one of the first conductive features closer to the substrate.

2. The semiconductor device of claim 1, wherein the first dielectric region contacts and extends along sidewalls of the first via.

3. The semiconductor device of claim 2, wherein the first dielectric region and the third dielectric layer comprise a same dielectric material.

4. The semiconductor device of claim 3, wherein an upper surface of the first dielectric region distal from the gate structure is flush with an upper surface of the second dielectric layer, and a lower surface of the first dielectric region facing the gate structure is flush with a lower surface of the second dielectric layer.

5. The semiconductor device of claim 4, further comprising a second via extending through the MCESL and electrically coupled to the gate structure, wherein the interconnect structure is electrically coupled to the second via, wherein the second via and the first via comprise different electrically conductive materials.

6. The semiconductor device of claim 5, further comprising a second dielectric region embedded in the second dielectric layer and around the second via, wherein the first dielectric region and the second dielectric region comprise a same material.

7. The semiconductor device of claim 6, wherein a first width of the first dielectric region, measured laterally between a sidewall of the first dielectric region and the first via, is larger than a second width of the second dielectric region measured laterally between a sidewall of the second dielectric region and the second via.

8. The semiconductor device of claim 1, wherein the interconnect structure further comprises:
a multi-layered dielectric structure over the MCESL, wherein the multi-layered dielectric structure and the MCESL have a same multi-layered structure and comprise same dielectric materials, wherein the plurality of ESLs and the plurality of dielectric layers are disposed over the multi-layered dielectric structure; and
a second conductive feature embedded in the multi-layered dielectric structure.

9. The semiconductor device of claim 8, further comprising a second dielectric region embedded in a second dielectric layer of the multi-layered dielectric structure and around the second conductive feature, wherein the first dielectric region and the second dielectric region comprise a same material.

10. The semiconductor device of claim 1, wherein an atomic percentage of oxygen in the second dielectric layer is lower than that in the third dielectric layer.

11. The semiconductor device of claim 1, wherein a hardness of the third dielectric layer is higher than that of the second dielectric layer.

12. A semiconductor device comprising:
a channel layer over a substrate and between source/drain regions;
a gate structure over the channel layer;
a gate spacer along a sidewall of the gate structure;
an interlayer dielectric (ILD) layer over the source/drain regions and around the gate structure, wherein the gate spacer and the gate structure are recessed from an upper surface of the ILD layer distal from the substrate, wherein the gate structure extends along at least a portion of an upper surface of the gate spacer distal from the substrate;
a source/drain contact extending through the ILD layer and electrically coupled to one of the source/drain regions;
a multi-layered middle contact etch stop layer (MCESL) over the ILD layer and the gate structure, comprising:
a first dielectric layer having a first dielectric constant;
a second dielectric layer over the first dielectric layer and having a second dielectric constant smaller than the first dielectric constant; and
a third dielectric layer over the second dielectric layer and having a third dielectric constant smaller than the first dielectric constant;
a first via extending through the MCESL and electrically coupled to the source/drain contact;
a first dielectric region embedded in the second dielectric layer and around the first via, wherein the first dielectric region and the second dielectric layer comprise different dielectric materials; and
an interconnect structure over the multi-layered MCESL and electrically coupled to the first via, wherein the interconnect structure comprises a plurality of dielectric layers and conductive features embedded in the plurality of dielectric layers.

13. The semiconductor device of claim 12, wherein the first dielectric region contacts sidewalls of the first via, wherein the first dielectric region and the second dielectric layer have a same thickness.

14. The semiconductor device of claim 13, wherein the first dielectric region and the third dielectric layer comprise a same dielectric material.

15. The semiconductor device of claim 14, further comprising:
a second via extending through the MCESL and electrically coupled to the gate structure, wherein the first via and the second via comprise different materials; and
a second dielectric region embedded in the second dielectric layer and around the second via, wherein the first dielectric region and the second dielectric region comprise a same dielectric material.

16. The semiconductor device of claim 14, wherein a third thickness of the third dielectric layer is larger than a second thickness of the second dielectric layer and larger than a first thickness of the first dielectric layer.

17. The semiconductor device of claim 14, wherein a second thickness of the second dielectric layer is larger than a third thickness of the third dielectric layer, wherein the third thickness of the third dielectric layer is larger than a first thickness of the first dielectric layer.

18. A method of forming a semiconductor device, the method comprising:
forming a gate structure over a channel layer, wherein the channel layer is disposed between source/drain regions;
forming a gate spacer along a sidewall of the gate structure;
forming an interlayer dielectric (ILD) layer over the source/drain regions and around the gate structure;
forming a source/drain contact that extends through the ILD layer and electrically couples to one of the source/drain regions;
forming a multi-layered middle contact etch stop layer (MCESL) over the ILD layer and the gate structure, comprising:
forming a first dielectric layer over the ILD layer and the gate structure;
forming a second dielectric layer over the first dielectric layer; and
forming a third dielectric layer over the second dielectric layer, wherein a first dielectric constant of the first dielectric layer is higher than a second dielectric constant of the second dielectric layer and a third dielectric constant of the third dielectric layer;
forming a first via opening in the multi-layered MCESL to expose the source/drain contact, wherein forming the first via opening comprises performing a first anisotropic etching process using a first etching mask;
after forming the first via opening, removing the first etching mask by performing a first plasma process;
after removing the first etching mask, treating the first via opening by performing a second plasma process, wherein the first plasma process and the second plasma process convert a portion of the second dielectric layer exposed to the first via opening into a first dielectric region, wherein the first dielectric region has a different material composition than the second dielectric layer;
after treating the first via opening, filling the first via opening with a first electrically conductive material to form a first via; and
forming an interconnect structure over the multi-layered MCESL and electrically coupled to the first via, wherein the interconnect structure comprises a plurality of dielectric layers and conductive features embedded in the plurality of dielectric layers.

19. The method of claim 18, further comprising, before forming the interconnect structure:
forming a second via opening in the multi-layered MCESL to expose the gate structure, wherein forming the second via opening comprises performing a second anisotropic etching process using a second etching mask;
after forming the second via opening, removing the second etching mask by performing a third plasma process, wherein the third plasma process converts a portion of the second dielectric layer exposed by the second via opening into a second dielectric region, wherein the first dielectric region and the second dielectric region comprise a same material; and
filling the second via opening with a second electrically conductive material different from the first electrically conductive material to form a second via, wherein the interconnect structure is formed to electrically couple to the second via.

20. The method of claim 19, wherein the first dielectric region extends laterally from the first via by a first distance, wherein the second dielectric region extends laterally from the second via by a second distance smaller than the first distance.
